(19) United States
(12) Patent Application Publication
(10) Pub. No.: US 2025/0287729 A1
(43) Pub. Date: Sep. 11, 2025

(54) METHOD FOR MANUFACTURING MICRODISPLAY PANEL

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,659

(22) PCT Filed: Feb. 5, 2024
(86) PCT No.: PCT/KR2024/001657

§ 371 Date: Oct. 27, 2024

(30) Foreign Application Priority Data
Feb. 7, 2023 (KR) 10-2023-0015994
Feb. 21, 2023 (KR) 10-2023-0022801
Feb. 21, 2023 (KR) 10-2023-0022807
Mar. 23, 2023 (KR) 10-2023-0037734
Mar. 27, 2023 (KR) 10-2023-0039809
Aug. 29, 2023 (KR) 10-2023-0113957
Jan. 3, 2024 (KR) 10-2024-0000814

(51) Int. Cl. H10H 20/01

(52) U.S. Cl. CPC H10H 20/018; H10H 20/013; H10H 20/032; H10H 20/0361; H10H 20/0364

(57) ABSTRACT

The present invention relates to a method for manufacturing a microdisplay panel in which a process for aligning LED stacks and CMOS electrode pads is not required, the method comprising: a first step of preparing a support wafer and a front wafer disposed on the support wafer and including a light-emitting portion in which a group 3-5 compound semiconductor is epitaxially grown, and preparing a back wafer having a plurality of CMOS electrode pads aligned on the upper surface thereof; a second step of bonding the front wafer to the back wafer through a bonding layer so that the light-emitting portion faces the CMOS electrode pads, and then removing the support wafer; and a third step of etching the light-emitting portion and the bonding layer to separate same in preset units, whereby the plurality of LED stacks are respectively aligned on the plurality of CMOS electrode pads.

### TECHNICAL FIELD

The present invention relates to a method of manufacturing a microdisplay panel, and more specifically, to a method of manufacturing a light-emitting diode on silicon (LEDoS) microdisplay panel, which does not require a process of arranging light-emitting diode (LED) stacks and complementary metal oxide semiconductor (CMOS) electrode pads through an engineering monolithic epitaxy wafer using a ceramic material when a front wafer and a back wafer are bonded.

### BACKGROUND ART

The types of implementation of the metaverse, which has recently been attracting attention, are classified into four types of virtual reality (VR)), augmented reality (AR), mixed reality (MR), and extended reality (XR). Among these, it is expected that a metaverse ecosystem will be developed in the future centered on XR that is a reality in which VR, AR and MR are combined. In order to effectively implement XR, there is a need for devices (for example, smart glasses or head-mounted displays) that include microdisplays with a diagonal length of less than 1 inch as a core component, along with software for next-generation computing platforms that can provide innovative user experiences. In particular, the development of high-performance microdisplay panel technologies is absolutely required to provide the greatest immersion, visibility, and convenience to XR users and minimize dizziness.

As shown in FIG. 1, a microdisplay panel 10 according to the related art is a technology in which an Si complementary metal oxide semiconductor (CMOS) semiconductor wafer process is combined with a high-resolution, high-luminance, and ultra-small display process. The microdisplay panel 10 of the related art may have a structure in which an Si CMOS wafer 11, which has a size of 8″ or more and a (100) crystal face and includes a plurality of CMOS electrode pads 12, is bonded to a transparent wafer 13, which has a size of less than 6″ and includes a micro-light-emitting diode (LED) electrode pad 14 and a plurality of micro-LED chips 15, through a conductive bonding portion 16. The types of microdisplay panels expected to be applied to XR devices include liquid crystal (LC)-based LC on Si (LCoS) panels, organic light-emitting diode (OLED)-based OLED on Si (OLEDoS) panels, and ultra-small micro-LED-based LED on Si (LEDoS) panels with a pixel size of less than 5 μm. VR devices to which low-pixel density displays are applied are being developed and mass-produced around LCOS and OLEDoS panels.

However, with the development of metaverse implementation technologies, there is an increasing need for lightweight AR, MR, and XR devices to which high-pixel density microdisplay panels are applied. In order to satisfy this need, there is an urgent need to develop an LEDoS technology which is considered to be an ideal solution in theory based on the superior properties of inorganic materials, but a microdisplay panel platform therefor has not yet been established.

LEDoS based on ultra-small micro-LEDs with a pixel size of less than 5 μm has advantages of an excellent power-to-performance ratio and a short response speed when applied to XR devices and has advantages in that inorganic materials are used to have a long lifespan, power is efficiently used to reduce heat generation, and a battery is usable for the long-term. In particular, since XR devices have a very short distance between a display and the eyes, even a little time delay in image conversion may easily cause discomfort such as dizziness. Therefore, LEDoS which has a nanosecond response speed is considered to be the most suitable for XR devices as compared to LCOS and OLEDoS which have a microsecond response speed.

Furthermore, it is evaluated that the biggest reason why LEDoS is attracting attention in AR, MR, and XR devices unlike in VR is due to luminance and luminous efficiency. Due to the characteristics of smart glasses that can be worn regardless of location, high brightness is an essential condition for normal operation even in outdoor environments such as sunlight, and in theory, micro-LEDs supports a luminance of tens to millions of nits, and while OLEDs are organic, micro-LEDs are inorganic and thus also have an advantage of high luminous efficiency.

However, despite the above-described advantages, the biggest reason why LEDoS based on ultra-small micro-LEDs with a pixel size of less than 5 μm are not used as a major component of XR devices is that LEDoS is difficult to mass-produce. That is, in LEDoS, since millions of ultra-small micro-LEDs should be fixed onto a Si CMOS wafer, the process difficulty is high and the yield is very low, which leads to an increase in manufacturing costs to generate a high component price. Thus, the high component price is reflected in the final consumer price, and the LEDoS is supplied as a high-priced XR device, which makes it difficult to meet market demand.

Meanwhile, as shown in FIG. 2, up to now, LEDoS using a Group III-V compound (GaN, GaP, or the like) micro-LED light source has been developed through traditional approaches such as \textcircled{1} monolithic integration of a wafer (or a unit die) consisting of micro-LED arrays on an Si CMOS wafer or \textcircled{2} hybridization between wafers (or unit dies) on a blue, green, or red light source wafer (or a unit die) on which Si CMOS wafers or micro-LED arrays are manufactured.

Up to now, one of the biggest obstacles to the development of LEDoS using blue, green, and red micro-LED light sources consisting of Group III-V compounds is that it is not easy to secure a solution for pixels having a size of less than 5 μm. Recently, 5 μm level pixels have been successfully demonstrated using monolithic integration technologies, and some product demonstrations developed based on hybridization technologies have been manufactured using sapphire flip chips to achieve 10 μm level pixels. In addition, CEA-Leti in France has demonstrated that it is possible to reduce pixels to a 5 μm level in the same way by using micro tube interconnections in hybridization technologies. However, both monolithic integration and hybridization technologies are impractical solutions with significant difficulties in mass production in terms of quality and yield and have a problem in that mass production is difficult.

The above-described monolithic integration technology and hybrid technology have the common characteristics in which a front plane wafer consisting of Group III-V compound micro-LED arrays and an Si CMOS back plane wafer consisting of a number of IC electrode pad arrays are each separately designed and manufactured and then assembled. Since micro-LED arrays manufactured at unit die-level or wafer-level on Si CMOS wafers should be arranged ultra-finely in any way, in this case, the arrangement is limited by the precision of a process-related device, which seriously affects pixels and pixel to pixel distance (pitch) limitations and causes a problem that mass production is also difficult. Accordingly, in order to manufacture LEDoS to which blue, green, and red micro-LED light sources which have high resolution and high luminance, are driven at a high speed, include pixels with a size of less than 5 μm, and have a pitch of less than 3 μm, are applied, there is a need for new alternative solutions that can solve the above-described ultra-fine arrangement constraints.

Accordingly, although several impressive product demonstrations, which include 6 μm pixels using engineering monolithic epitaxy wafers manufactured through a low-temperature metal bonding process between an Si CMOS wafer and a micro-LED array wafer, have been recently released, mass production is considered impossible due to low quality and yield issues caused by low-temperature metal bonding and the use of wafers with a small diameter of 6 inches or less. Above all, when ultra-fine pixels with a size of less than 3 μm for microdisplays are manufactured using conventional engineering monolithic epitaxy wafers through metal bonding, a patterning etching process faces even greater difficulties.

As another example, a novel engineering monolithic epitaxy wafer approach, which has made significant progress in solving a problem of a limitation on the brightness and resolution of LEDoS with Group III-V compound micro-LED light sources and simultaneously is capable of providing mass production and low-cost manufacturing solutions through the use of 12-inch diameter Si CMOS wafers, has been proposed. As shown in FIG. 3, specifically, in the corresponding technology, a process using an engineering monolithic epitaxy wafer is performed through the following four operations: \textcircled{1} an LED epitaxy sawn to a final microdisplay panel size (4 mm×6 mm) is arranged and bonded onto a 12 inch Si blank wafer at a unit die level, and an LED initial growth wafer and a buffer layer are removed to perform planarization and leave only a 1.5 μm thick LED active layer on the large diameter Si blank wafer, \textcircled{2} the LED active layer left on the Si blank wafer is bonded to an Si CMOS wafer through multilayer metal bonding at a wafer level, \textcircled{3} the 12 inch Si blank wafer is removed, and then \textcircled{4} a micro-LED array that serves as a pixel is directly patterned on a Si CMOS wafer and manufactured.

However, in operation \textcircled{1}, when an LED epitaxy die is bonded onto the Si blank wafer, there is a limitation in that the die should be bonded by arranging a position on an Si CMOS integrated circuit (IC) wafer with the same size, in operation \textcircled{2}, when the LED active layer is bonded with multilayer metals including low-melting-point metals (Sn and In), there is a problem in that a discharge phenomenon in which low-melting-point metal components overflow relatively easily occurs to cause short circuit defects in which micro-LED sub-pixel arrays in a panel are electrically connected to each other or are connected to neighboring CMOS IC electrode pad arrays adjacent thereto, and in operation \textcircled{4}, there is a problem in that accurate ultra-fine patterning is difficult due to an opaque multilayer metal bonding layer, and defects are caused by the re-deposition of multilayer metal layer byproducts generated in a plasma dry process.

That is, the engineering monolithic epitaxy wafer approach presented in the above-described technologies is evaluated as a solution that is a step closer to implementing LEDoS based on ultra-small micro-LEDs with a pixel size of less than 5 μm. However, there are quality and yield issues due to the use of metals (low temperature, multilayer) in wafer bonding, it is very difficult to manufacture high-resolution microdisplays including ultra-fine pixels with a size of less than 3 μm, and there are also problems according to some arrangement processes. Thus, a new alternative is needed for this.

Furthermore, when a transparent conductive electrode of indium tin oxide (ITO), zinc oxide (ZnO), or the like is used in manufacturing the above-described microdisplays, there is a disadvantage in that bonding strength with other layers is low due to the characteristics of the transparent conductive electrode, which is a ceramic material, and thus there is a need for a method of solving this disadvantage.

### DISCLOSURE

### Technical Problem

The present invention is directed to solving the above-described conventional problems and providing a method of manufacturing a microdisplay panel, which manufactures a light-emitting diode on silicon (LEDoS) microdisplay panel without a need for a process of arranging light-emitting diode (LED) stacks and complementary metal oxide semiconductor (CMOS) electrode pads through an engineering monolithic epitaxy wafer using a ceramic material when a front wafer and a back wafer are bonded.

### Technical Solution

According to the present invention, the above object is achieved by a method of manufacturing a microdisplay panel, which does not require a process of arranging light-emitting diode (LED) stacks and complementary metal oxide semiconductor (CMOS) electrode pads, the method including a first operation of preparing a front wafer including a support wafer and a light-emitting portion and preparing a back wafer having a plurality of CMOS electrode pads arranged on an upper surface thereof, wherein the light-emitting portion is disposed on the support wafer and formed by epitaxially growing a Group III-IV compound semiconductor, a second operation of bonding the front wafer onto the back wafer through a bonding layer such that the light-emitting portion faces the CMOS electrode pad, and then removing the support wafer, and a third operation of etching the light-emitting portion and the bonding layer to be divided into preset units, and arranging the plurality of LED stacks on the plurality of CMOS electrode pads.

In addition, the bonding layer may be formed of a ceramic material that is optically transparent and electrically conductive.

In addition, the ceramic material may be a transparent conductive oxide (TCO), a transparent conductive nitride (TCN), or a transparent conductive oxynitride (TCON).

In addition, in the second operation, before the bonding of the front wafer onto the back wafer, surfaces of the bonding layer of the front wafer and the bonding layer of the back wafer may each be polished and planarized.

In addition, the support wafer and the back wafer may be silicon (Si) wafers.

In addition, the light-emitting portion may include a first semiconductor region having first conductivity, a second semiconductor region having second conductivity that is different from the first conductivity, and an active region interposed between the first semiconductor region and the second semiconductor region and configured to generate light using the recombination of electrons and holes.

In addition, an electrode that is in ohmic contact with and electrically connected to the light-emitting portion may be formed on at least one of an upper surface and a lower surface of the light-emitting portion.

In addition, the electrode may be formed of a material that is optically transparent and electrically conductive.

In addition, a surface of the electrode may be polished and planarized.

According to the present invention, the above object is achieved by a method of manufacturing a vertically stacked microdisplay panel, which does not require a process of arranging LED stacks and CMOS electrode pads, the method including a first operation of preparing a plurality of front wafers, each of which includes a support wafer and a light-emitting portion and emits light having different colors, and preparing a back wafer having a plurality of CMOS electrode pads arranged on an upper surface thereof, wherein the light-emitting portion is disposed on the support wafer and formed by epitaxially growing a Group III-IV compound semiconductor, a second operation of repeating a process of bonding the front wafer on the back wafer through bonding layers and then removing the support wafer to vertically stack the plurality of light-emitting portions and bonding layers on the back wafer, and a third operation of etching the plurality of vertically stacked light-emitting portions and bonding layers to be divided into preset units to arrange the plurality of LED stacks on the plurality of CMOS electrode pads.

In addition, the bonding layer may be formed of a ceramic material that is optically transparent and electrically conductive.

In addition, the ceramic material may be a TCO, a TCN, or a TCON.

In addition, the plurality of front wafers may include a first front wafer configured to emit light having a first color, a second front wafer configured to emit light having a second color different from the first color, and a third front wafer configured to emit light having a third color different from the first color and the second color.

In addition, the method may further include a fourth operation of forming a common electrode on the plurality of LED stacks and forming a color filter on the common electrode.

In addition, in the second operation, before the bonding of the front wafer onto the back wafer, surfaces of the bonding layer of the front wafer and the bonding layer of the back wafer may each be polished and planarized.

In addition, the support wafer and the back wafer may be silicon (Si) wafers.

In addition, the light-emitting portion may include a first semiconductor region having first conductivity, a second semiconductor region having second conductivity that is different from the first conductivity, and an active region interposed between the first semiconductor region and the second semiconductor region and configured to generate light using recombination of electrons and holes.

In addition, an electrode that is in ohmic contact with and electrically connected to the light-emitting portion may be formed on at least one of an upper surface and a lower surface of the light-emitting portion.

In addition, the electrode may be formed of a material that is optically transparent and electrically conductive.

In addition, a surface of the electrode may be polished and planarized.

According to the present invention, the above object is achieved by a method of manufacturing a microdisplay panel, which does not require a process of arranging LED stacks and CMOS electrode pads, the method including a first operation of preparing a front wafer including a support wafer and a light-emitting portion and preparing a back wafer having a plurality of CMOS electrode pads arranged on an upper surface thereof, wherein the light-emitting portion is disposed on the support wafer and formed by epitaxially growing a Group III-IV compound semiconductor, a second operation of bonding the front wafer onto the back wafer through a bonding layer, and then removing the support wafer, and a third operation of etching the light-emitting portion and the bonding layer to be divided into preset units, and arranging the plurality of LED stacks on the plurality of CMOS electrode pads, wherein the CMOS electrode pad includes a reflective layer configured to reflect light generated from the light-emitting portion.

In addition, the CMOS electrode pad may be formed as a single layer or multiple layers.

In addition, the reflective layer may be formed of aluminum (Al).

In addition, the bonding layer may be formed of a ceramic material that is optically transparent and electrically conductive.

In addition, the ceramic material may be a TCO, a TCN, or a TCON.

In addition, the support wafer and the back wafer may be silicon (Si) wafers.

In addition, an electrode that is in ohmic contact with and electrically connected to the light-emitting portion may be formed on at least one of an upper surface and a lower surface of the light-emitting portion.

In addition, the electrode may be formed of a ceramic material that is optically transparent and electrically conductive.

In addition, in the first operation, a plurality of front wafers configured to emit light having different colors may be prepared, in the second operation, a process of bonding the front wafer onto the back wafer through the bonding layer, and then removing the support wafer may be repeated to vertically stack the plurality of light-emitting portions and bonding layers on the back wafer, and in the third operation, the stacked plurality of light-emitting portions and bonding layers may be etched and divided into preset units.

According to the present invention, the above object is achieved by a method of manufacturing a microdisplay panel, which does not require a process of arranging LED stacks and CMOS electrode pads, the method including a first operation of preparing a front wafer and a back wafer, wherein the front wafer includes a support wafer, a light-emitting portion disposed on the support wafer and formed by epitaxially growing a Group III-IV compound semiconductor, and an electrode which is formed on at least one of an upper surface and a lower surface of the light-emitting portion and is optically transparent and electrically conductive, and the back wafer includes a plurality of CMOS electrode pads arranged on an upper surface thereof, a second operation of bonding the front wafer onto the back wafer through a bonding layer such that the light-emitting portion faces the CMOS electrode pad, and then removing the support wafer, and a third operation of etching the light-emitting portion, the electrode, and the bonding layer to be divided into preset units to arrange the plurality of LED stacks on the plurality of CMOS electrode pads, wherein a bonding reinforcement layer configured to reinforce bonding strength of the electrode is formed on at least one of an upper surface and a lower surface of the electrode.

In addition, the bonding reinforcement layer may be formed of a material that is optically transparent and electrically conductive.

In addition, the bonding reinforcement layer may be formed of a TCA.

In addition, the TCA may be formed of metal nanoparticles.

In addition, the TCA may be formed of a polymer matrix in which TCO particles are dispersed.

In addition, the TCA may be formed of a polymer matrix in which metal particles are dispersed.

In addition, the polymer may be formed of a material that is optically transparent.

In addition, the bonding reinforcement layer may be formed of an anisotropic conductive film (ACF).

In addition, the bonding layer is formed of a ceramic material that is optically transparent and electrically conductive.

In addition, the ceramic material may be a TCO, a TCN, or a TCON.

### Advantageous Effects

According to the present invention, unlike conventional monolithic integration methods or hybrid methods in which arrangement issues are present, since a stack on an engineering monolithic epitaxy wafer is etched and divided into preset units to allow a plurality of light-emitting diode (LED) stacks to be arranged on a plurality of complementary metal oxide semiconductor (CMOS) electrode pads, not only wafers with a small diameter of 6 inches or less, but also wafers with a large diameter of 8 inches or more can be used, which has the effect of considerably increasing the yield of products.

In addition, according to the present invention, since a ceramic material rather than metal is used for a bonding layer and an ohmic contact electrode, there are effects of considerably reducing the possibility of electrical short circuit detects and considerably increasing the reliability of a device. In addition, a plasma dry process of arranging LED stacks has effects in which etching is easy, and simultaneously the problem of re-deposition of etch by-products does not occur. Moreover, the above-described ease of etching provides an advantage in that it is much more advantageous for manufacturing high-resolution microdisplays including ultra-fine pixels with a size of less than 3 μm.

In addition, according to the present invention, since a light-emitting portion, a bonding layer, and an ohmic contact electrode are all transparent to transmit visible light, there is an effect of no arrangement error issue in an exposure process.

In addition, according to the present invention, since a reflective layer to which an aluminum (Al) reflector is applied is formed on a CMOS electrode pad below a transparent stack layer structure, there is an advantage in which an amount of light loss can be minimized.

In addition, according to the present invention, the bonding strength of a transparent electrode can be considerably reinforced through a bonding reinforcement layer formed on an upper surface and/or a lower surface of the transparent electrode, and thus there is an effect of considerably increasing the durability of a manufactured microdisplay panel.

Meanwhile, the effects of the present invention are not limited to the above-described effects, and various effects may be included within the range apparent to those skilled in the art from contents to be described below.

### DESCRIPTION OF DRAWINGS

FIG. 1 illustrates a structure of a microdisplay panel of a related art.

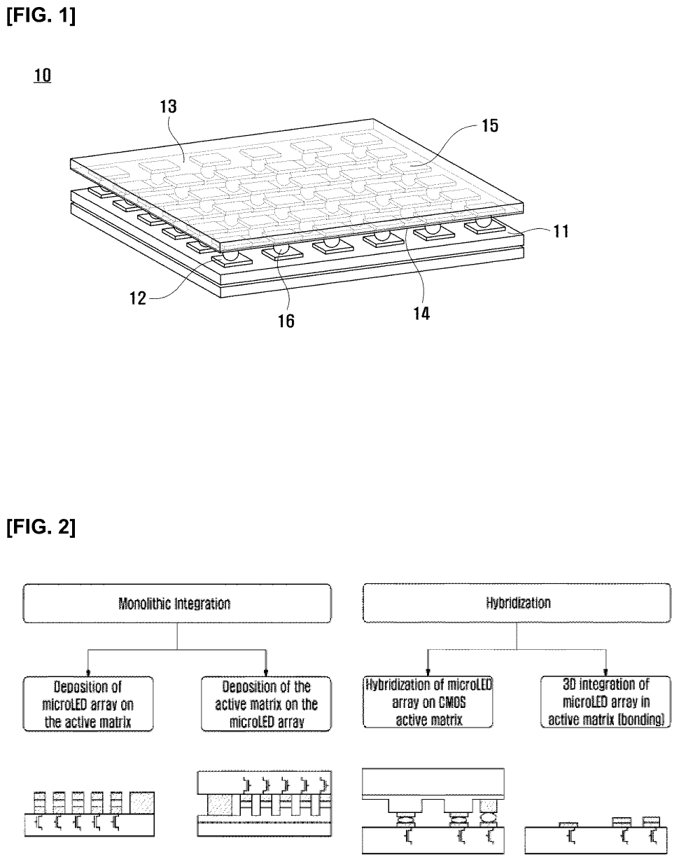

FIG. 2 illustrates a light-emitting diode on silicon (LEDoS) development approach of a related art.

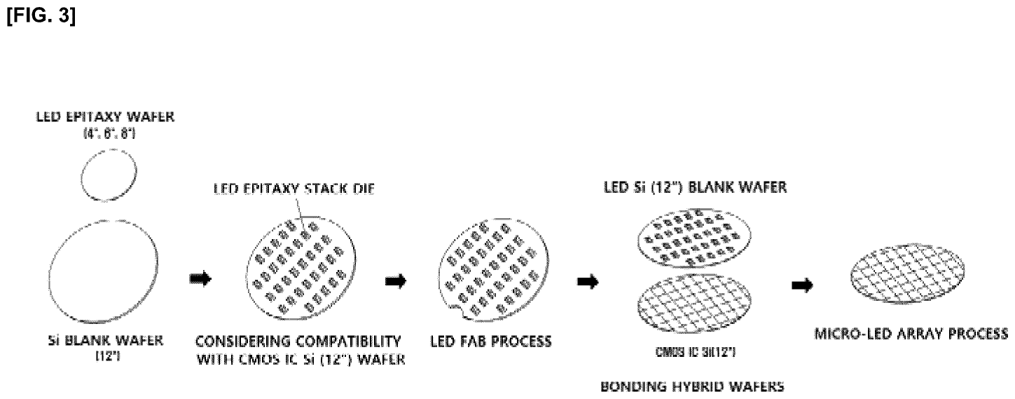

FIG. 3 illustrates an approach using an engineering monolithic epitaxy wafer of a related art.

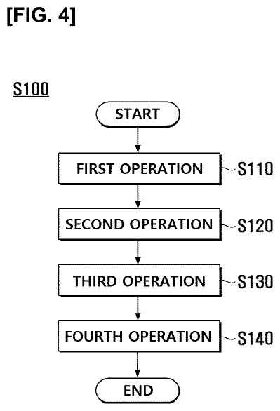

FIG. 4 is a flowchart of a method of manufacturing a microdisplay panel according to a first embodiment of the present invention.

FIG. 5 illustrates a process of manufacturing a microdisplay panel according to the method of manufacturing a microdisplay panel according to the first embodiment of the present invention.

FIG. 6 illustrates a case in which a front wafer used in the method of manufacturing a microdisplay panel according to the first embodiment of the present invention has a p-side up or n-side up form.

FIG. 7 illustrates a first front wafer used in the method of manufacturing a microdisplay panel according to the first embodiment of the present invention.

FIG. 8 illustrates a second front wafer used in the method of manufacturing a microdisplay panel according to the first embodiment of the present invention.

FIG. 9 illustrates a process of forming the second front wafer used in the method of manufacturing a microdisplay panel according to the first embodiment of the present invention.

FIG. 10 illustrates a third front wafer used in the method of manufacturing a microdisplay panel according to the first embodiment of the present invention.

FIG. 11 illustrates a process of forming the third front wafer used in the method of manufacturing a microdisplay panel according to the first embodiment of the present invention.

FIG. 12 illustrates a fourth front wafer or a fifth front wafer used in the method of manufacturing a microdisplay panel according to the first embodiment of the present invention.

FIG. 13 illustrates a process of forming the fourth front wafer or the fifth front wafer used in the method of manufacturing a microdisplay panel according to the first embodiment of the present invention.

FIGS. 14 and 15 illustrate a microdisplay panel according to the first embodiment of the present invention.

FIG. 16 is a flowchart of a method of manufacturing a microdisplay panel according to a second embodiment of the present invention.

FIGS. 17 and 18 illustrate a process of manufacturing a plurality of front wafers in an n-side up form in the method of manufacturing a microdisplay panel according to the second embodiment of the present invention.

FIGS. 19 and 20 illustrate a process of manufacturing a plurality of front wafers in a p-side up form in the method of manufacturing a microdisplay panel according to the second embodiment of the present invention.

FIGS. 21 to 23 illustrate a process of manufacturing a vertically stacked microdisplay panel according to the method of manufacturing a microdisplay panel according to the second embodiment of the present invention.

FIG. 24 illustrates a vertically stacked microdisplay panel manufactured according to the method of manufacturing a microdisplay panel according to the second embodiment of the present invention.

FIG. 25 illustrates a case in which a complementary metal oxide semiconductor (CMOS) electrode pad to which a reflector is applied is a single layer in the method of manufacturing a microdisplay panel according to the first or second embodiment of the present invention.

FIG. 26 illustrates a case in which a CMOS electrode pad to which a reflector is applied is a multilayer in the method of manufacturing a microdisplay panel according to the first or second embodiment of the present invention.

FIG. 27 illustrates the reflectivity of reflectors applicable to a CMOS electrode pad in the method of manufacturing a microdisplay panel according to the first or second embodiment of the present invention.

FIG. 28 illustrates that a bonding reinforcement layer is formed on each of an upper surface and a lower surface of an electrode in the method of manufacturing a microdisplay panel according to the first or second embodiment of the present invention.

FIG. 29 illustrates various bonding reinforcement layers in the method of manufacturing a microdisplay panel according to the first or second embodiment of the present invention.

### MODES OF THE INVENTION

Hereinafter, some embodiments of the present invention will be described in detail with the accompanying exemplary drawings. When assigning reference numerals refer to components of each drawing, although the same components are illustrated in different drawings, the same components are given the same reference numerals as much as possible.

Further, in describing the present invention, a detailed description of related known configurations and functions will be omitted when it is determined that it may obscure the understanding of the embodiments of the present invention.

In addition, in describing components of the embodiment of the present invention, terms such as first, second, A, B, (a), and (b) may be used. These terms are used to distinguish one component from another component. However, the nature, the order, the sequence, or the number of components is not limited by these terms.

Hereinafter, a method S100 of manufacturing a microdisplay panel according to a first embodiment of the present invention will be described in detail with reference to the accompanying drawings.

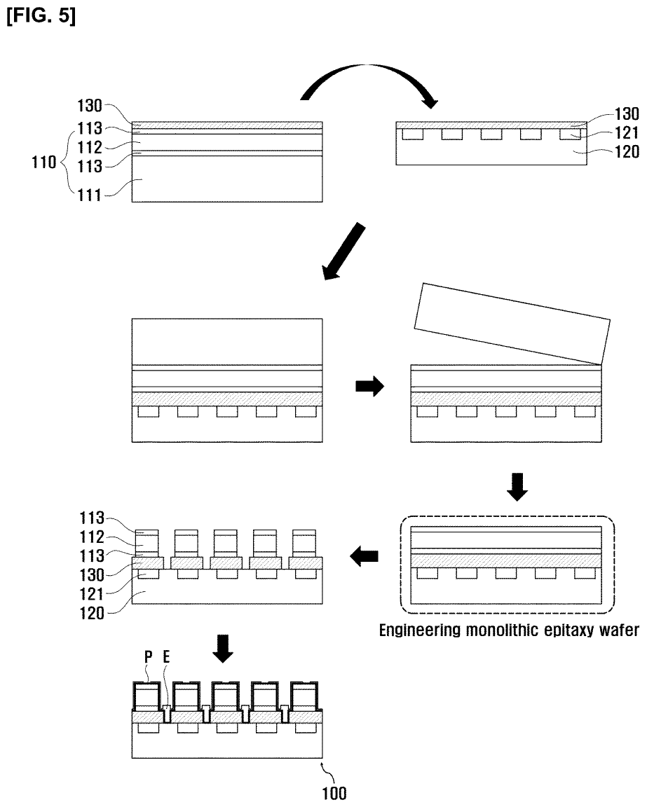

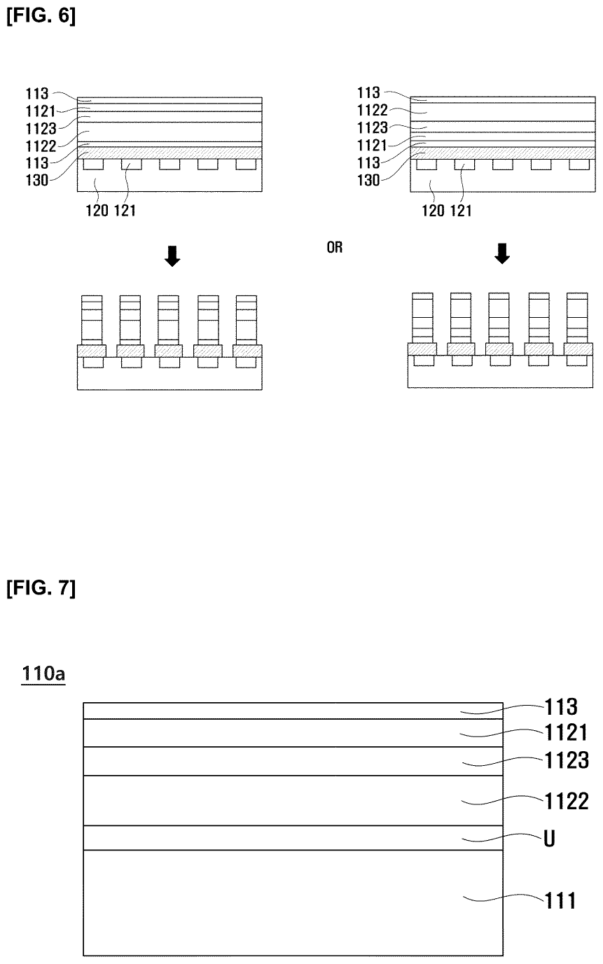

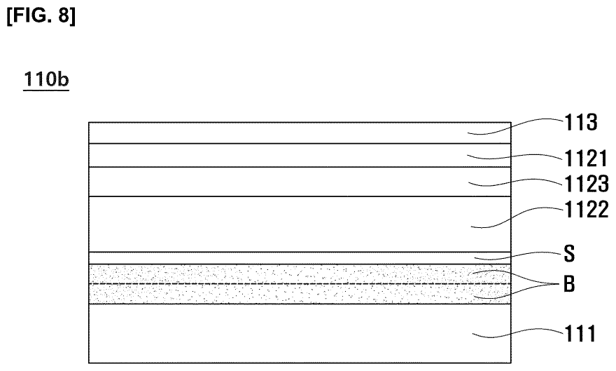

FIG. 4 is a flowchart of the method of manufacturing a microdisplay panel according to the first embodiment of the present invention. FIG. 5 illustrates a process of manufacturing a microdisplay panel according to the method of manufacturing a microdisplay panel according to the first embodiment of the present invention. FIG. 6 illustrates a case in which a front wafer used in the method of manufacturing a microdisplay panel according to the first embodiment of the present invention has a p-side up or n-side up form.

As shown in FIGS. 4 and 5, the present invention relates to a method of manufacturing a microdisplay panel, which does not require an arrangement process of a light-emitting diode (LED) stack and a complementary metal oxide semiconductor (CMOS) electrode pad 121. The method S100 of manufacturing a microdisplay panel according to the first embodiment of the present invention includes a first operation S110, a second operation S120, a third operation S130, and a fourth operation S140.

The first operation S110 is an operation of preparing a front wafer 110 and a back wafer 120.

More specifically, the front wafer 110 includes a support wafer 111, a light-emitting portion 112, and an electrode 113.

The support wafer 111 supports the light-emitting portion 112 disposed thereon. The support wafer 111 is provided as a silicon (Si) wafer having a (111), (110), or (100) crystal face to prevent quality issues from occurring due to a difference in thermal expansion coefficient when the front wafer 110 is bonded to the back wafer 120 to be described below.

The light-emitting portion 112 generates light and is disposed on the support wafer 111. The light-emitting portion 112 may emit blue light, green light, or red light. In the present invention, when the light-emitting portion 112 emits blue light or green light, binary, ternary, and quaternary compounds such as InN, InGaN, GaN, AlGaN, AlN, and AlGaInN, which are Group III (Al, Ga, and In) nitride semiconductors among Group III-V compound semiconductors, may be disposed at an appropriate position and order on an initial growth wafer G and epitaxially grown.

In particular, in order to emit blue light or green light, a high-quality Group III nitride semiconductor such as InGaN having a high indium (In) composition should be preferentially formed on a Group III nitride semiconductor consisting of GaN, AlGaN, AlN, or AlGaInN, but the present invention is not limited thereto.

In addition, in the present invention, when the light-emitting portion 112 emits red light, binary, ternary, and quaternary compounds such as InP, InGaP, GaP, AlInP, AlGaP, AlP, and AlGaInP, which are Group III (Al, Ga, and In) phosphide semiconductors among Group III-V compound semiconductors, may be disposed at an appropriate position and order on the initial growth wafer and epitaxially grown.

In particular, in order to emit red light, a high-quality Group III phosphide semiconductor such as InGaP having a high indium (In) composition should be preferentially formed on a Group III phosphide semiconductor consisting of GaP, AlInP, AlGaP, AlP, or AlGaInP, but the present invention is not limited thereto.

The light-emitting portion 112 may include, more specifically, a first semiconductor region 1121 (for example, a p-type semiconductor region), an active region 1123 (for example, a multi-quantum well (MQW)), and a second semiconductor region 1122 (for example, an n-type semiconductor region). The light-emitting portion 112 may have a structure in which the second semiconductor region 1122, the active region 1123, and the first semiconductor region 1121 are sequentially and epitaxially grown on the initial growth substrate G and may typically have an overall thickness of about 5.0 μm to about 8.0 μm by ultimately including a plurality of layers of Group III nitrides, but the present invention is not limited thereto.

Each of the first semiconductor region 1121, the active region 1123, and the second semiconductor region 1122 may be provided as a single layer or multiple layers, and although not shown, before the light-emitting portion 112 is epitaxially grown on the initial growth wafer, necessary layers such as a buffer layer may be added to improve the quality of the epitaxially grown light-emitting portion 112. For example, the buffer layer may typically have a thickness of about 4.0 μm by including a compliant layer consisting of a nucleation layer and an un-doped semiconductor region to relieve stress and improve thin film quality. In addition, when the initial growth wafer G is removed using a laser lift-off (LLO) technique, a sacrificial layer may be provided between the nucleation layer and the un-doped semiconductor region, and a seed layer may also serve as the sacrificial layer.

The second semiconductor region 1122 has second conductivity (n-type) and is formed on the initial growth wafer G. This second semiconductor region 1122 may have a thickness of 2.0 μm to 3.5 μm.

The active region 1123 generates light using the recombination of electrons and holes and is formed on the second semiconductor region 1122. The active regions 1123 may be provided as a plurality of layers to have a thickness of several tens of nm.

The first semiconductor region 1121 has first conductivity (p-type) and is formed on the active region 1123. The first semiconductor region 1121 may be provided as a plurality of layers to have a thickness of several tens of nm to several um, and an upper surface thereof may have gallium (Ga) polarity.

That is, the active region 1123 is interposed between the first semiconductor region 1121 and the second semiconductor region 1122 so that holes of the first semiconductor region 1121, which is a p-type semiconductor region, recombine with electrons of the second semiconductor region 1122, which is an n-type semiconductor region, in the active region 1123 to generate light.

Meanwhile, before the front wafer 110 and the back wafer 120 are bonded through a bonding layer 130, the electrode 113, which is transparent, has conductivity and is in ohmic contact with and electrically connected to the light-emitting portion 112, may be formed on at least one of upper and lower surfaces of the light-emitting portion 112, which will be described below.

Meanwhile, as shown in FIG. 6, the light-emitting portion 112 of the front wafer 110 of the present invention may have a (p-up) structure in which the second semiconductor region 1122, the active region 1123, and the first semiconductor region 1121 are sequentially stacked, and the first semiconductor region 1121, which is a p-type semiconductor, is positioned at an upper side, or may have an (n-up) structure in which the first semiconductor region 1121, the active region 1123, and the second semiconductor region 1122 are sequentially stacked, and the second semiconductor region 1122, which is an n-type semiconductor, is positioned at an upper side.

More specifically, in the present invention, the front wafer 110 may have a first structure, a second structure, a third structure, a fourth structure, or a fifth structure.

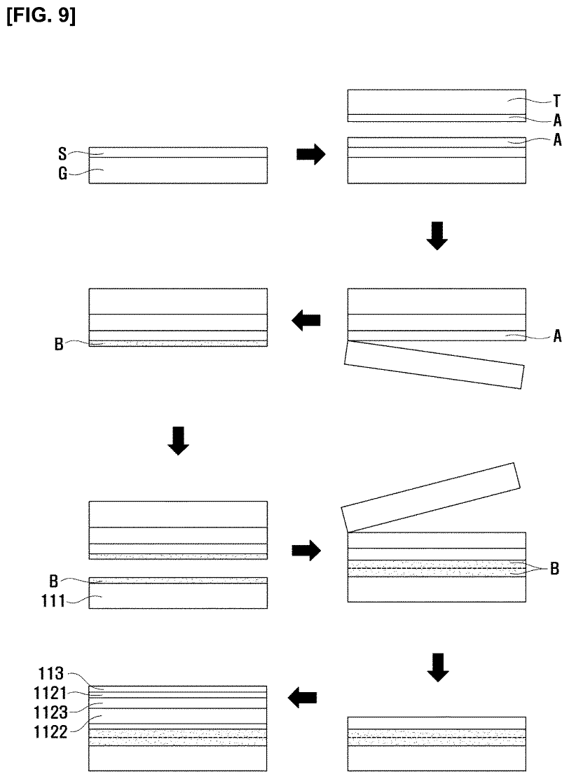

FIG. 7 illustrates a first front wafer used in the method of manufacturing a microdisplay panel according to the first embodiment of the present invention.

As shown in FIG. 7, a first front wafer 110a of the present invention has a first structure in which the light-emitting portion 112 is epitaxially grown directly on a silicon (Si) growth wafer G having a (111) crystal face, and then the electrode 113, which is transparent and conductive, is formed on an upper surface of the first semiconductor region 1121.

Accordingly, the first front wafer 110a has a structure in which a buffer layer U, the second semiconductor region 1122, the active region 1123, the first semiconductor region 1121, and the electrode 113 are sequentially stacked on the silicon (Si) growth wafer G having a (111) crystal face, and thus has a (p-side up) structure in which the first semiconductor region 1121, which is a p-type semiconductor, is disposed at an upper side, and has a structure in which the electrode 113 is disposed on an upper surface of the light-emitting portion 112.

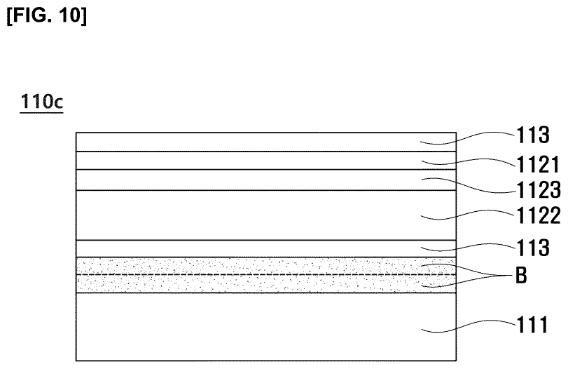

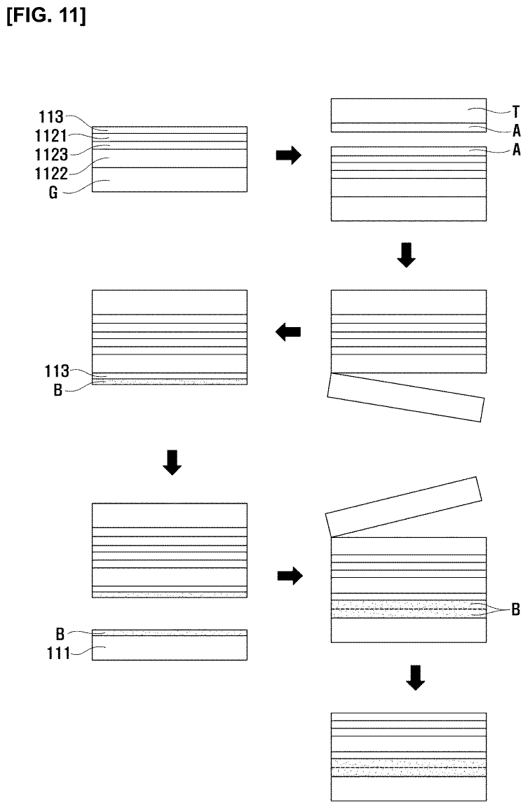

FIG. 8 illustrates a second front wafer used in the method of manufacturing a microdisplay panel according to the first embodiment of the present invention. FIG. 9 illustrates a process of forming the second front wafer used in the method of manufacturing a microdisplay panel according to the first embodiment of the present invention.

As shown in FIGS. 8 and 9, a second front wafer 110b of the present invention has a second structure in which the light-emitting portion 112 is grown directly on a Group III nitride semiconductor template, and a process of manufacturing the second front wafer 110b is as follows. First, a Group III nitride semiconductor seed layer S is epitaxially grown on a sapphire (α-phase Al₂O₃) growth wafer G which is a wafer that is optically transparent to (theoretically) transmit 100% of a laser beam (single wavelength light) without absorbing the laser beam and has high temperature resistance, and a temporary wafer T (preferably formed of sapphire), which has a thermal expansion coefficient that is the same or similar to that of the growth wafer G, is bonded to an upper surface of the seed layer S through an adhesive layer A. Thereafter, the growth wafer G is separated from the seed layer S using an LLO technique, and a silicon (Si) support wafer 111 having a (111), (110), or (100) crystal face is bonded to a lower surface of the seed layer S through a bonding layer B. Thereafter, the Group III nitride semiconductor template is manufactured by separating the temporary wafer T from the adhesive layer A using an LLO technique and etching and removing the adhesive layer A. Afterwards, the light-emitting portion 112 is epitaxially grown on the seed layer S of the Group III nitride semiconductor template, and then the electrode 113, which is transparent and conductive, is formed on an upper surface of the first semiconductor region 1121.

Accordingly, the second front wafer 110b has a structure in which the silicon (Si) support wafer 111 having a (111), (110), or (100) crystal face, the bonding layer B, the seed layer S, the second semiconductor region 1122, the active region 1123, the first semiconductor region 1121, and the electrode 113 are sequentially stacked and thus has a (p-side up) structure in which the first semiconductor region 1121, which is a p-type semiconductor, is disposed at an upper side, and has a structure in which the electrode 113 is disposed on an upper surface of the light-emitting portion 112.

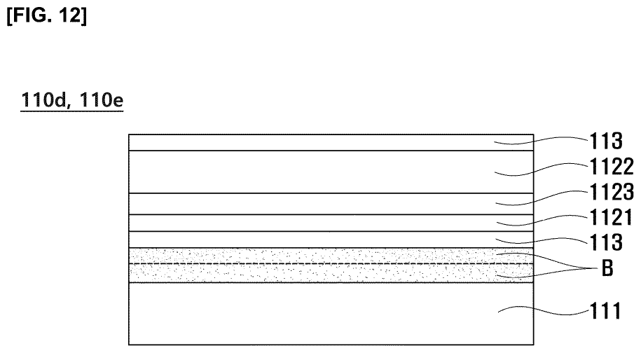

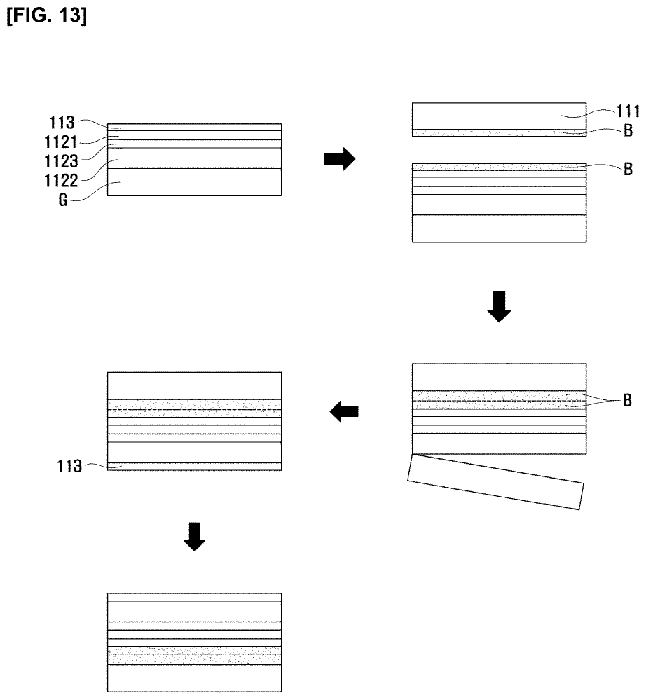

FIG. 10 illustrates a third front wafer used in the method of manufacturing a microdisplay panel according to the first embodiment of the present invention, and FIG. 11 illustrates a process of forming the third front wafer in method of manufacturing a microdisplay panel according to the first embodiment of the present invention.

As shown in FIGS. 10 and 11, a third front wafer 110c of the present invention has a third structure in which bonding is performed twice, and an LLO technique is performed twice, and a process of manufacturing the third front wafer 110c is as follows. First, when a sapphire (α-phase Al₂O₃) growth wafer G (light-emitting portion 112), which is a wafer that is optically transparent to (theoretically) transmit 100% of a laser beam (single wavelength light) without absorbing the laser beam and has high temperature resistance, emits red light, the second semiconductor region 1122, the active region 1123, and the first semiconductor region 1121 are sequentially stacked on the GaAs growth wafer G to epitaxially grow the light-emitting portion 112, and an electrode 113, which is transparent and conductive, is formed on an upper surface of the first semiconductor region 1121, and then a silicon (Si) temporary wafer T having a (111), (110), or (100) crystal face is bonded to the electrode 113 through an adhesive layer A. Thereafter, the growth wafer G is separated from the light-emitting portion 112 using an LLO technique, an electrode 113, which is transparent and conductive, is formed on a lower surface of the second semiconductor region 1122, and then a silicon (Si) support wafer 111 having a (111), (110), or (100) crystal face is bonded to the electrode 113 through a bonding layer B. Thereafter, the temporary wafer T is separated from the adhesive layer A using an LLO technique, and the adhesive layer A is etched and removed (when the light-emitting portion 112 emits red light, a chemical lift-off (CLO) technique is used).

Accordingly, the third front wafer 110c has a structure in which the silicon (Si) support wafer 111 having a (111), (110), or (100) crystal face, the bonding layer B, the electrode 113, the second semiconductor region 1122, the active region 1123, the first semiconductor region 1121, and the electrode 113 are sequentially stacked and thus has a (p-side up) structure in which the first semiconductor region 1121, which is a p-type semiconductor, is disposed at an upper side, and has a structure in which the electrode 113 is disposed on an upper surface or a lower surface of the light-emitting portion 112.

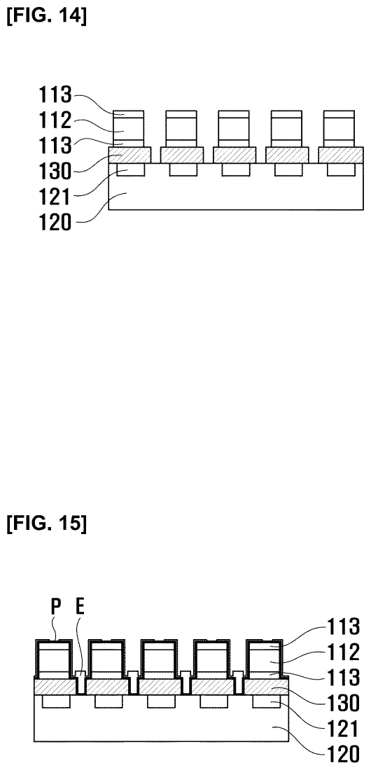

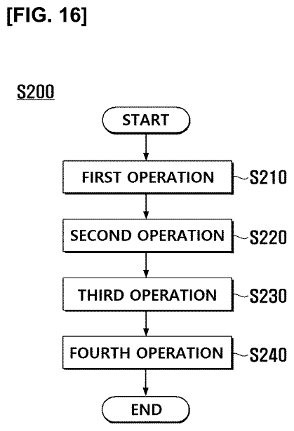

FIG. 12 illustrates a fourth front wafer or a fifth front wafer used in the method of manufacturing a microdisplay panel according to the first embodiment of the present invention. FIG. 13 illustrates a process of forming the fourth front wafer or the fifth front wafer used in the method of manufacturing a microdisplay panel according to the first embodiment of the present invention.

As shown in FIGS. 12 and 13, a fourth front wafer 110d of the present invention has a fourth structure in which bonding is performed once and an LLO technique is performed once, and a process of manufacturing the fourth front wafer 110d is as follows.

First, when a silicon (Si) growth wafer G (light-emitting portion 112) having a (111) crystal face emits red light, the first semiconductor region 1121, the active region 1123, and the second semiconductor region 1122 are sequentially stacked on a GaAs growth wafer G to epitaxially grow the light-emitting portion 112, an electrode 113, which is transparent and conductive, is formed on an upper surface of the second semiconductor region 1122, and then a silicon (Si) support wafer 111 having a (111), (110), or (100) crystal face is bonded to the electrode 113 through a bonding layer B. Thereafter, the growth wafer G is separated from the light-emitting portion 112 using an LLO technique, and an electrode 113, which is transparent and conductive, is formed on a lower surface of the first semiconductor region 1121.

Accordingly, the fourth front wafer 110d has a structure in which the silicon (Si) support wafer 111 having a (111), (110), or (100) crystal face, the bonding layer B, the electrode 113, the first semiconductor region 1121, the active region 1123, the second semiconductor region 1122, and the electrode 113 are sequentially stacked and thus has an (n-side up) structure in which the second semiconductor region 1122, which is an n-type semiconductor, is disposed at an upper side, and has a structure in which the electrode 113 is disposed on an upper surface or a lower surface of the light-emitting portion 112. In addition, the silicon (Si) support wafer 111 has no difference in thermal expansion coefficient when the fourth front wafer 110d is bonded to the silicon (Si) back wafer 120, thereby contributing to stabilizing the quality of the microdisplay panel 100.

Meanwhile, the fifth front wafer 110e of the present invention has a fifth structure in which bonding is performed once and LLO is performed once, and a process of manufacturing the fifth front wafer 110e is the same as that of the fourth front wafer 110d, except that, when a sapphire (α-phase Al₂O₃) growth wafer G (light-emitting portion 112), which is a wafer that is optically transparent to (theoretically) transmit 100% of a laser beam (single wavelength light) without absorbing the laser beam and has high temperature resistance, emits red light, the growth wafer G is a GaAs growth wafer G, and thus redundant descriptions thereof will be omitted.

Accordingly, similar to the fourth front wafer 110d, the fifth front wafer 110e has a structure in which the silicon (Si) support wafer 111 having a (111), (110), or (100) crystal face, the bonding layer B, the electrode 113, the first semiconductor region 1121, the active region 1123, the second semiconductor region 1122, and the electrode 113 are sequentially stacked and thus has an (n-side up) structure in which the second semiconductor region 1122, which is an n-type semiconductor, is disposed at an upper side, and has a structure in which the electrode 113 is disposed on the upper surface or the lower surface of the light-emitting portion 112.

The silicon (Si) support wafer 111 of the first to fifth front wafers 110a to 110e has no difference in thermal expansion coefficient when bonded to the silicon (Si) back wafer 120, thereby contributing to quality stabilization.

Furthermore, in the first to fifth front wafers 110a to 110e, when a surface (Ga polarity surface) of the first semiconductor region 1121 or a surface (N polarity surface) of the second semiconductor region 1122 is exposed, in order to have a smooth surface, the surfaces may each be polished and smoothly planarized through mechanical polishing (MP) or chemical-mechanical polishing (CMP).

Meanwhile, the electrode 113 of the first to fifth front wafers 110a to 110e is formed of a material which is transparent and conductive. When the electrode 113 is formed in contact with the first semiconductor region 1121 which is a p-type semiconductor, a material of the electrode 113 may include NiO, PtO, PdO, AgO₂, Au, Rh₂O₃, RuO₂, In₂O₃, SnO₂, zinc oxide (ZnO), indium zinc oxide (IZO), indium tin oxide (ITO), and indium germanium zinc oxide (IGZO). When the electrode 113 is formed in contact with the second semiconductor region 1122 which is an n-type semiconductor, a material of the electrode 113 may include TiN, CrN, VN, In₂O₃, SnO₂, ZnO, IZO, ITO, and IGZO.

Furthermore, since the surface of the second semiconductor region 1122 having N polarity has a much higher surface roughness than the surface of the first semiconductor region 1121 having Ga polarity, it is preferable to introduce a CMP process of polishing and planarizing the surface of the second semiconductor region 1122 before forming the electrode 113 which is transparent and conductive. In addition, each of the surfaces of the electrodes 113 formed on the first to fifth front wafers 110a to 110e may also be polished and smoothly planarized through MP or CMP.

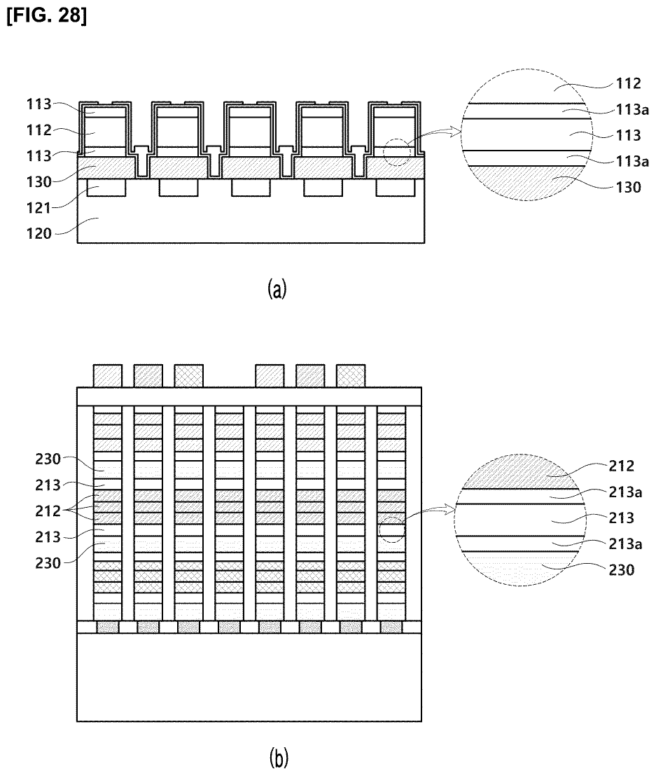

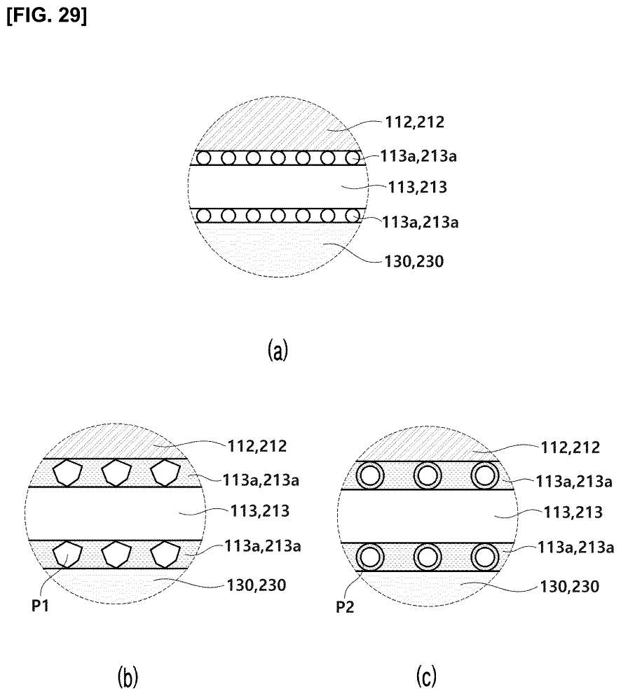

FIG. 28 illustrates that a bonding reinforcement layer is formed on each of an upper surface and a lower surface of an electrode in the method of manufacturing a microdisplay panel according to the first or second embodiment of the present invention. FIG. 29 illustrates various bonding reinforcement layers in the method of manufacturing a microdisplay panel according to the first or second embodiment of the present invention.

Meanwhile, as shown in FIG. 28, a bonding reinforcement layer 113a may be formed on at least one of an upper surface and a lower surface of the electrode 113.

When a transparent conductive material such as ITO or ZnO is used for the electrode 113, there is a disadvantage in that the bonding strength with other layers is low due to the characteristics of the transparent conductive material, which is a ceramic material.

The bonding reinforcement layer 113a of the present invention may be for reinforcing the bonding strength of the electrode 113 and may be formed of a material that is optically transparent and electrically conductive. The bonding reinforcement layer 113a may be formed before and after the formation of the electrode 113 in an operation of preparing the front wafer 110 in the first operation S110.

For example, when a front wafer 110 with an n-side up form is prepared, after the bonding reinforcement layer 113a is first formed on an upper surface of the first semiconductor region 1121 to form the electrode 113, the bonding reinforcement layer 113a may be formed on the upper surface of the electrode 113, and then the support wafer 111 and the bonding reinforcement layer 113a may be bonded through a bonding layer. In addition, after the bonding reinforcement layer 113a is first formed on a lower surface of the second semiconductor region 1122 with a reduced thickness to form the electrode 113, the bonding reinforcement layer 113a may be formed on the lower surface of the electrode 113, and then the bonding layer 130 may be deposited and formed on the bonding reinforcement layer 113a on the lower surface of the electrode 113.

The bonding reinforcement layer 113a may include a transparent conductive adhesive (TCA) or an anisotropic conductive film (ACF).

When the bonding reinforcement layer 113a is formed of a TCA, the TCA may include a polymer matrix in which metal nanoparticles and transparent conductive oxide particles are dispersed or a polymer matrix in which metal particles are dispersed.

More specifically, as shown in FIG. 29A, when a TCA is formed of metal nanoparticles, after the metal nanoparticles are deposited on a surface of the electrode to a thickness of 50 nm or less (preferably, to a thickness of 10 nm or less), when heat is applied, the metal nanoparticles are oxidized, thereby reinforcing the bonding strength between the electrode and other layers and also causing the bonding reinforcement layer 113a to become optically transparent (except for in the case of Au or the like). The metal nanoparticles may include In, Sn, Zn, Ga, Ag, or Au.

In addition, the TCA may be prepared as a polymer matrix in which particles are dispersed to reinforce the bonding strength between the electrode and other layers.

As shown in FIG. 29B, when a TCA is prepared as a polymer matrix in which transparent conductive oxide particles Pl are dispersed, the TCA may include ITO, IZO, IGZO, NiO, PtO, PdO, AgO₂, Rh₂O₃, RuO₂, In₂O₃, SnO₂, or ZnO, and a polymer may include an optically transparent non-conductive organic material or the like.

In addition, as shown in FIG. 29C, when a TCA is prepared as a polymer matrix in which metal particles are dispersed, metal particles P2 may be prepared as spherical metal particles P2 of which surfaces are coated with a metal and which have a hollow interior, a metal may include Ag, Au, Cu, Pt, Pd, or the like, and a polymer may include an optically transparent non-conductive organic material or the like.

In addition, the bonding reinforcement layer 113a may be provided as an ACF, and the ACF may include conductive particles disposed in an insulating resin binder. The conductive particles may include a metal such as Ag, Au, Cu, Pt, Pd, In, Sn, or Zn, and an alloy thereof, and the insulating resin binder may be formed of an optically transparent non-conductive organic material or the like.

Meanwhile, the bonding reinforcement layer 113a is not limited to the materials described above and may include various materials that are optically transparent and electrically conductive while also reinforcing the bonding strength between the electrode and other layers.

The back wafer 120 is a CMOS wafer in which, as an active driving integrated circuit (IC) driven through an active matrix (AM) method, a plurality of CMOS electrode pads 121 are arrayed on an upper surface thereof.

Here, the back wafer 120 is provided as a silicon (Si) wafer having a (100) crystal face and is preferably provided as an 8-inch or 12-inch silicon (Si) wafer according to a standard CMOS IC process.

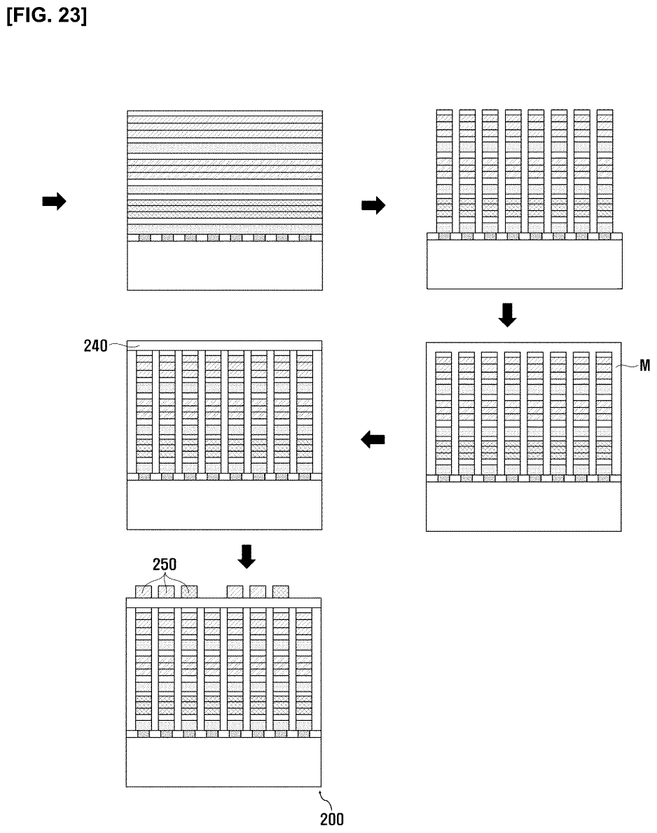

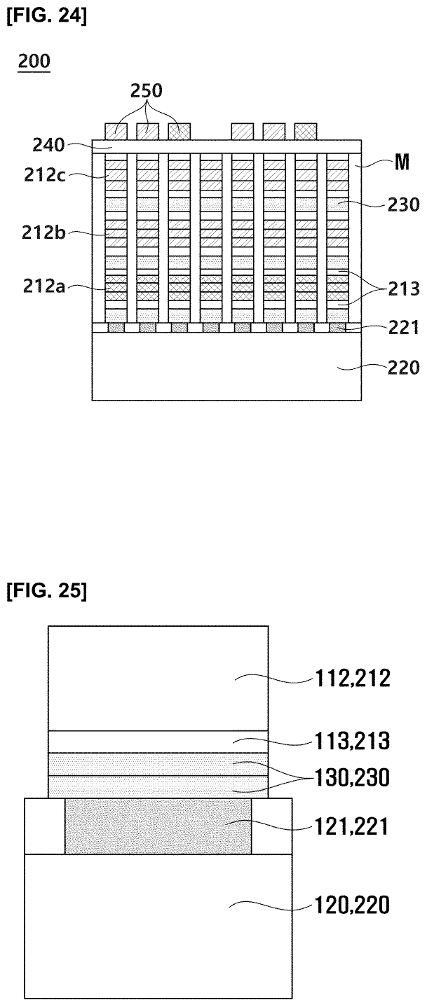

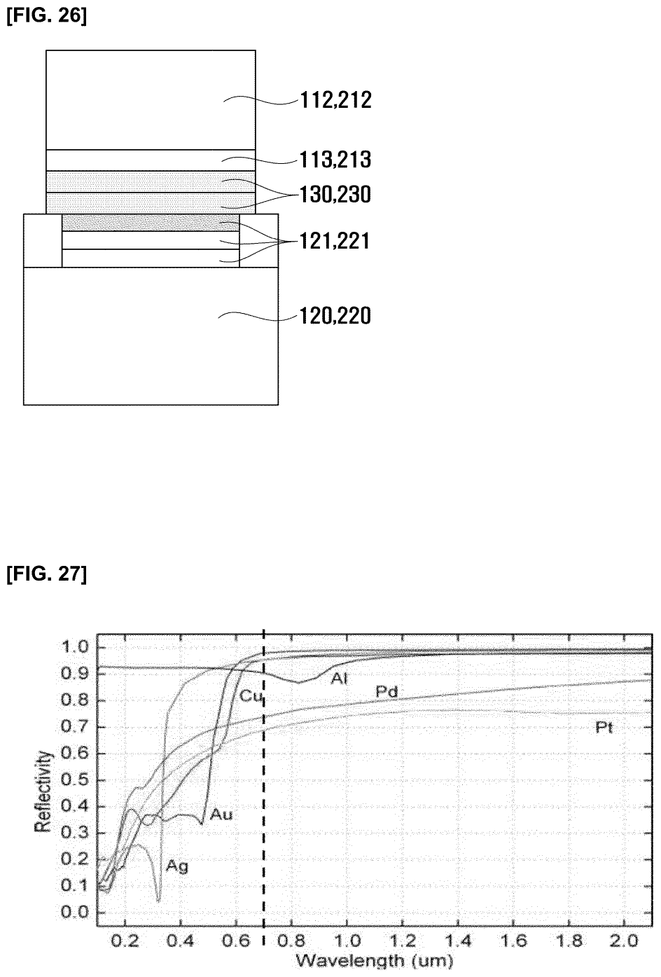

FIG. 25 illustrates a case in which a CMOS electrode pad to which a reflector is applied is a single layer in the method of manufacturing a microdisplay panel according to the first or second embodiment of the present invention. FIG. 26 illustrates a case in which a CMOS electrode pad to which a reflector is applied is a multilayer in the method of manufacturing a microdisplay panel according to the first or second embodiment of the present invention. FIG. 27 illustrates the reflectivity of reflectors applicable to a CMOS electrode pad in the method of manufacturing a microdisplay panel according to the first or second embodiment of the present invention.

As shown in FIG. 25 and FIG. 26, the CMOS electrode pad 121 may be formed as a single layer or multiple layers, and the CMOS electrode pad 121 may include a reflective layer that reflects light generated from the light-emitting portion 112.

In the microdisplay panel 100 of the present invention, since an LED stack including the light-emitting portion 112, the bonding layer, and the electrode 113 is optically transparent, an amount of light loss is determined according to the reflectivity of a material below the bonding layer, that is, the reflectivity of the CMOS electrode pad 121.

Accordingly, the CMOS electrode pad 121 may include a reflective layer that reflects light generated from the light-emitting portion 112, and as shown in FIG. 27, the reflective layer may be formed of aluminum (Al) having excellent reflectivity at a short wavelength of 700 nm or less.

In this case, when the CMOS electrode pad 121 is formed as a single layer, the CMOS electrode pad 121 may be formed as a single layer of aluminum (Al), and when the CMOS electrode pad 121 is formed as multiple layers due to additional needs for improved adhesion and a barrier function, the CMOS electrode pad 121 may be formed as multiple layers of Cu/Al, Cu/Ti/Al, Cu/Ni/Al, Cu/Cr/Al, or the like. However, when the CMOS electrode pad 121 is formed as multiple layers, it is preferable that a surface of the CMOS electrode pad 121 is formed of aluminum (Al) that has excellent reflectivity at short wavelengths.

According to the CMOS electrode pad 121 including the above-described reflective layer formed of aluminum (Al), there is an advantage in that an amount of light loss of the microdisplay panel can be minimized.

The second operation S120 is an operation of bonding an inverted front wafer 110 onto the back wafer 120 through the bonding layer such that the light-emitting portion 112 of the front wafer 110 faces the CMOS electrode pad 121 of the back wafer 120, that is, the light-emitting portion 112 of the front wafer 110 and the CMOS electrode pad 121 of the back wafer 120 face each other, and removing the support wafer 111 of the front wafer 110.

Here, since the support wafer 111 of the front wafer 110 is a silicon (Si) wafer having a (111), (110), or (100) crystal face, and the back wafer 120 is also a silicon (Si) wafer having a (100) crystal face, there is no difference in thermal expansion coefficient during bonding, thereby contributing to stabilizing the quality of a microdisplay panel.

In this case, the second operation S120 uses properties in which smooth surfaces adhere to each other due to van der Waals forces without using a high voltage or an external electric field. Accordingly, it is preferable that, before the front wafer 110 and the back wafer 120 are bonded through the bonding layer, a CMP process is introduced so that the roughness of each bonding surface is very low (Rq<0.5 nm @ 2 μm×2 μm) and there are no particles such as impurities between surfaces. To this end, in the second operation S120, before the front wafer 110 is bonded to the back wafer 120, surfaces of the bonding layer of the front wafer 110 and the bonding layer of the back wafer 120 may each be polished and smoothly planarized through MP or CMP. Afterwards, in the second operation S120, after the front wafer 110 is bonded to the back wafer 120, it is necessary perform heat treatment on the bonding layer at a temperature of less than 400° C. such that a CMOS circuit of the back wafer 120 is not damaged.

In addition, the bonding layer in the second operation S120 is formed of a ceramic material which is transparent and conductive, and the ceramic material which is transparent and conductive includes a transparent conductive oxide (TCO), a transparent conductive nitride (TCN), and a transparent conductive oxide nitride (TCON).

In this case, when the ceramic material is a TCO, the ceramic material may include In₂O₃, SnO₂, ZnO, IZO, ITO, and IGZO, when the ceramic material is a TCN, the ceramic material may include TiN, CrN, and VN, and when the ceramic material is a TCON, the ceramic material may include InON, SnON, ZnON, IZON, ITON, and IGZON.

Thereafter, in the second operation S120, the support wafer 111 of the front wafer 110 is removed through MP or CMP, and if necessary, an SiO₂ layer, a seed layer, a bonding layer, and the like are also removed, for example, after MP, they are removed through a chemical etching solution (TMA), plasma etching, or the like.

In this case, after the support wafer 111 is removed, a structure is formed in which the back wafer 120, the bonding layer 130 which is transparent and conductive, and the transparent light-emitting portion 112 (p-side up or n-side up) are sequentially stacked, and a structure is formed in which the electrode 113, which is transparent and conductive, is formed on an upper or a lower surface of the light-emitting portion 112. That is, a transparent stacked layer structure is formed on a CMOS IC wafer consisting of an array of CMOS electrode pads 121, thereby forming an engineering monolithic epitaxy wafer structure of the present invention.

The third operation S130 is an operation of etching the light-emitting portion 112, the bonding layer 130, and the electrode 113 to be divided into preset units (pixel or subpixel units) to arrange a plurality of LED stacks to be disposed on the plurality of CMOS electrode pads 121 and an operation that eliminates the need for a conventional process of arranging the LED stacks of the front wafer 110 and the CMOS electrode pads 121 of the back wafer 120.

That is, in the third operation S130, the light-emitting portion 112, the bonding layer 130, and the electrode 113 are vertically etched until a surface of the back wafer 120 or an area adjacent thereto is exposed to align the plurality of LED stacks on the arrayed, that is, arranged, CMOS electrode pads 121. In this case, the light-emitting portion 112, the bonding layer 130, and the electrode 113 of the present invention are all transparent to transmit visible light, and thus there is an advantage in that there is no arrangement error issue in an exposure process. In addition, since a ceramic material is used rather than a metal, both the bonding layer 130 and the electrode 113 of the present invention are easy to etch in a plasma dry process, and there is an advantage in that there is no problem of re-deposition of etching by-products.

The fourth operation S140 is an operation of performing a fab process on the plurality of LED stacks arranged on the back wafer 120. That is, a light-emitting diode on silicon (LEDoS) structure is completed by performing a fab process of forming a passivation layer P configured to cover the light-emitting portion 112, the bonding layer 130, and the electrode 113, and forming a connection electrode E electrically connected to the light-emitting portion 112.

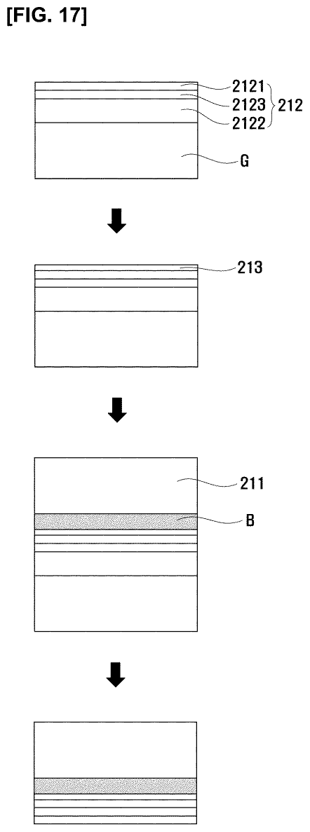

FIGS. 14 and 15 illustrate a microdisplay panel according to the first embodiment of the present invention.

As shown in FIGS. 14 and 15, the microdisplay panel 100, which is manufactured according to the method S100 of manufacturing a microdisplay panel according to the first embodiment of the present invention which includes the first operation S110, the second operation S120, the third operation S130, and the fourth operation S140 as described above, includes the back wafer 120 having a plurality of CMOS electrode pads 121 arranged on an upper surface thereof, the bonding layer 130 disposed on the back wafer 120, and the light-emitting portion 112 which is disposed on the bonding layer 130 and in which a Group III-V compound semiconductor is epitaxially grown. The microdisplay panel 100 has a structure in which the electrode 113 is formed on at least one of the upper surface and the lower surface of the light-emitting portion 112, and the light-emitting portion 112, the bonding layer 130, and the electrode 113 are etched to be divided into preset units so that a plurality of LED stacks are arranged on a plurality of arranged CMOS electrode pads 121. Here, the bonding layer 130 and the electrode 113 are formed of a ceramic material which is transparent and conductive.

In addition, after a structure in which the plurality of LED stacks are arranged on the plurality of CMOS electrode pads 121 is formed, a fab process is performed to form a passivation layer P configured to cover the light-emitting portion 112, the bonding layer 130, and the electrode 113, and form a connection electrode E electrically connected to the light-emitting portion 112, thereby completing the LEDoS microdisplay panel 100 structure.

In addition, the bonding reinforcement layer 113a may be formed on at least one of an upper surface and a lower surface of the electrode 113, and the CMOS electrode pad 121 may include a reflective layer that reflects light generated from the light-emitting portion 112.

Hereinafter, a method S200 of manufacturing a microdisplay panel according to the second embodiment of the present invention will be described in detail with reference to the accompanying drawings.

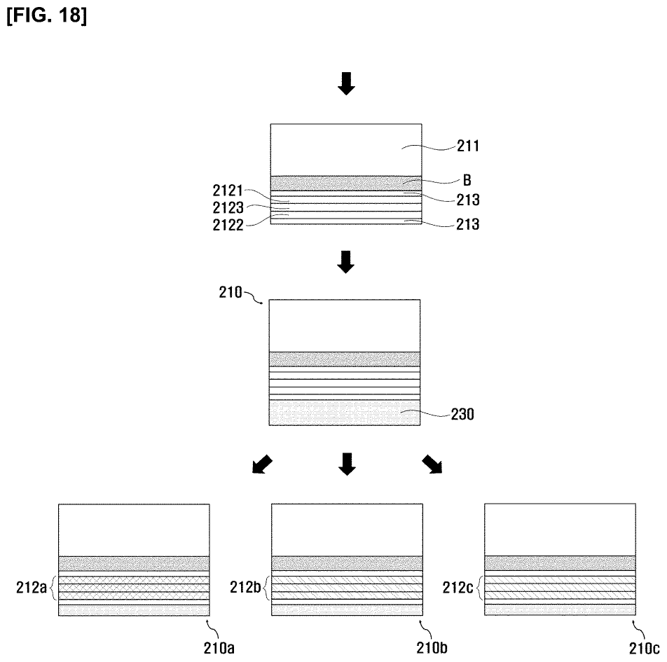

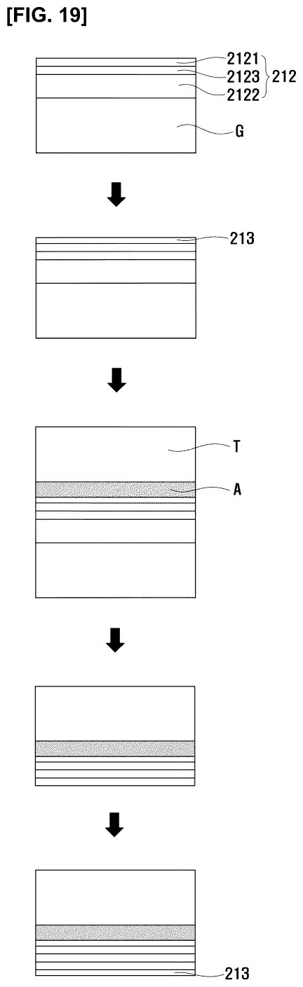

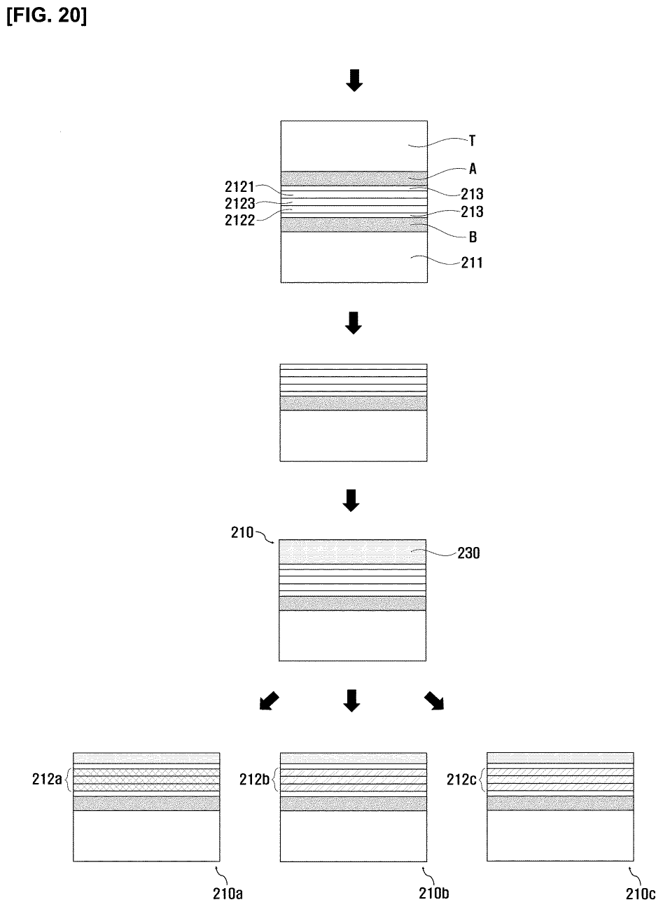

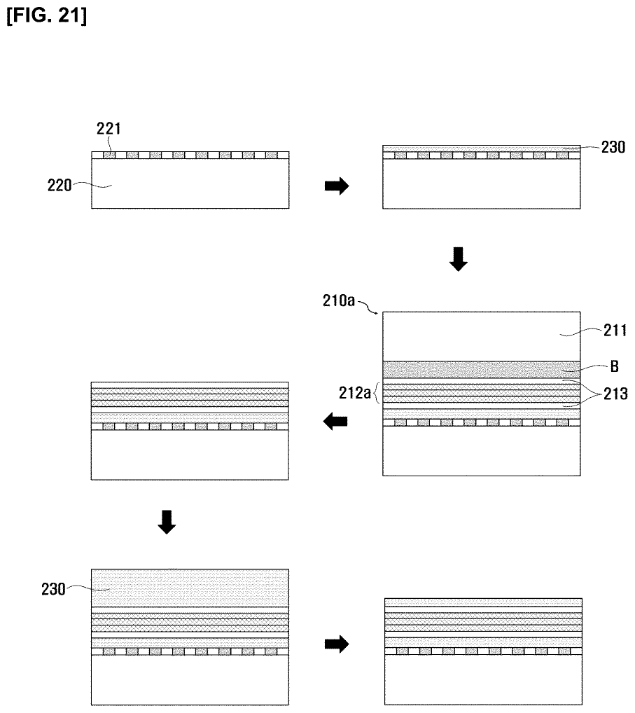

FIG. 16 is a flowchart of the method of manufacturing a microdisplay panel according to the second embodiment of the present invention. FIGS. 17 and 18 illustrate a process of manufacturing a plurality of front wafers in an n-side up form in the method of manufacturing a microdisplay panel according to the second embodiment of the present invention. FIGS. 19 and 20 illustrate a process of manufacturing a plurality of front wafers in a p-side up form in the method of manufacturing a microdisplay panel according to the second embodiment of the present invention. FIGS. 21 to 23 illustrate a process of manufacturing a vertically stacked microdisplay panel according to the method of manufacturing a microdisplay panel according to the second embodiment of the present invention.

As shown in FIGS. 16 to 23, the present invention relates to a method of manufacturing a vertically stacked microdisplay panel, which does not require a process of arranging LED stacks and CMOS electrode pads 221, and the method S200 of manufacturing a microdisplay panel according to the second embodiment of the present invention includes a first operation S210, a second operation S220, a third operation S230, and a fourth operation S240.

The first operation S210 is an operation of preparing a plurality of front wafers 210 and preparing a back wafer 220.

The plurality of front wafers 210 may emit light having different colors, and the plurality of front wafers 210 may include a first front wafer 210a that emits light having a first color, a second front wafer 210b that emits light having a second color different from the first color, and a third front wafer 210c that emits light having a third color different from the first and second colors. In this case, the first color may be red, the second color may be green, and the third color may be blue, but the present invention is not limited thereto.

More specifically, the first front wafer 210a, the second front wafer 210b, and the third front wafer 210c each include a support wafer 211, a light-emitting portion 212 (including one of a first light-emitting portion 212a, a second light-emitting portion 212b, and a third light-emitting portion 212c) disposed on the support wafer 211, and an electrode 213.

The support wafer 211 supports the light-emitting portion 212 disposed thereon. The support wafer 211 is provided as a silicon (Si) wafer having a (111), (110), or (100) crystal face to prevent quality issues from occurring due to a difference in thermal expansion coefficient when the first front wafer 210a is bonded to the back wafer 220 to be described below.

The light-emitting portion 212 generates light and may emit blue light, green light, or red light. Since the following contents are the same as those of the light-emitting portion 112 in the method S100 of manufacturing a microdisplay panel according to the first embodiment of the present invention described above, redundant descriptions thereof will be omitted.

Meanwhile, the front wafer 210 of the present invention may be manufactured in an n-side up form in which a second semiconductor region 2122 having second conductivity (n type) is exposed to the outside or in a p-side up form in which a first semiconductor region 2121 having first conductivity (p type) is exposed to the outside.

As shown in FIG. 17 and FIG. 18, in a case in which the front wafer 210 of the present invention is manufactured in the n-side up form in which the second semiconductor region 2122 having the second conductivity (n type) is exposed to the outside is a case in which a growth wafer G is removed by performing bonding once, and a process is as follows.

First, when the light-emitting portion 212 emits blue light or green light, the second semiconductor region 2122, an active region 2123, and the first semiconductor region 2121 are sequentially stacked on a sapphire (α-phase Al₂O₃) growth wafer G, which is a wafer that is optically transparent to (theoretically) transmit 100% of a laser beam (single wavelength light) without absorbing the laser beam and has high temperature resistance, to epitaxially grow the light-emitting portion 212, an electrode 213, which is transparent and conductive, is formed on an upper surface of the first semiconductor region 2121, and then a silicon (Si) support wafer 211 having a (111), (110), or (100) crystal face is bonded to the electrode 213 through a bonding layer B. Thereafter, the growth wafer G is separated from the light-emitting portion 212 using an LLO technique, the second semiconductor region 2122 is etched to reduce a thickness of the second semiconductor region 2122, an electrode 213, which is transparent and conductive, is formed on a lower surface of the second semiconductor region 2122 with the reduced thickness,, and then a bonding layer 230 is deposited and formed on the lower electrode 213, thereby preparing a front wafer 210 with an n-side up form.

On the other hand, a light-emitting portion 212 that emits blue or green light may be formed on silicon (Si) growth wafer G having a (111) crystal face instead of the sapphire (α-phase Al₂O₃) growth wafer G, and in this case, the silicon (Si) growth wafer G may be separated and removed through MP or a CLO technique.

In addition, when the light-emitting portion 212 emits red light, the second semiconductor region 2122, the active region 2123, and the first semiconductor region 2121 are sequentially stacked on a GaAs growth wafer G to epitaxially grow the light-emitting portion 212, an electrode 213, which is transparent and conductive, is formed on the upper surface of the first semiconductor region 2121, and then the silicon (Si) support wafer 211 having a (111), (110), or (100) crystal face is bonded to the electrode 213 through a bonding layer B. Thereafter, the growth wafer G is separated from the light-emitting portion 212 using a CLO technique, the second semiconductor region 2122 is etched to reduce a thickness of the second semiconductor region 2122, an electrode 213, which is transparent and conductive, is formed on the lower surface of the second semiconductor region 2122 with the reduced thickness,, and then the bonding layer 230 is deposited and formed on the lower electrode 213, thereby preparing a front wafer 210 with an n-side up form.

Accordingly, when the front wafer 210 has the n-side up form, the front wafer 210 has a structure in which the silicon (Si) support wafer 211 having a (111), (110), or (100) crystal face, the bonding layer B, the electrode 213, the first semiconductor region 2121, the active region 2123, the second semiconductor region 2122, the electrode 213, and the bonding layer 230 are sequentially stacked. The silicon (Si) support wafer 211 has no difference in thermal expansion coefficient when the front wafer 210 is bonded to the silicon (Si) back wafer 220 later, thereby contributing to stabilizing the quality of a vertically stacked microdisplay panel.

In addition, as shown in FIGS. 19 and 20, a case in which the front wafer 210 of the present invention is manufactured in the p-side up form in which the first semiconductor region 2121 having the first conductivity (p type) is exposed to the outside is a case in which the growth wafer G and a temporary wafer T are removed by performing bonding twice, and a process is as follows.

First, when the light-emitting portion 212 emits blue light or green light, the second semiconductor region 2122, the active region 2123, and the first semiconductor region 2121 are sequentially stacked on the sapphire (α-phase Al₂O₃) growth wafer G, which is a wafer that is optically transparent to (theoretically) transmit 100% of a laser beam (single wavelength light) without absorbing the laser beam and has high temperature resistance, to epitaxially grow the light-emitting portion 212, an electrode 213, which is transparent and conductive, is formed on the upper surface of the first semiconductor region 2121, and then a silicon (Si) temporary substrate T having a (111), (110), or (100) crystal face is bonded to the electrode 213 through an adhesive layer A. Thereafter, the growth wafer G is separated from the light-emitting portion 212 using an LLO technique, the second semiconductor region 2122 is etched to reduce a thickness of the second semiconductor region 2122, an ohmic contact electrode 213, which is transparent and conductive, is formed on the lower surface of the second semiconductor region 2122 with the reduced thickness, and then the silicon (Si) support wafer 211 having a (111), (110), or (100) crystal face is bonded to the ohmic contact electrode 213 through a bonding layer B. Thereafter, the temporary wafer T is separated from the adhesive layer A using a CLO technique, the adhesive layer A is etched and removed, and the bonding layer 230 is deposited and formed on the ohmic contact electrode 213 at the top, thereby preparing a front wafer 210 with a p-side up form.

On the other hand, a light-emitting portion 212 that emits blue or green light may be formed on silicon (Si) growth wafer G having a (111) crystal face instead of the sapphire (α-phase Al₂O₃) growth wafer G, and in this case, the silicon (Si) growth wafer G and the support wafer 211 are separated and removed through MP or a CLO technique.

In addition, when the light-emitting portion 212 emits red light, the second semiconductor region 2122, the active region 2123, and the first semiconductor region 2121 are sequentially stacked on the GaAs growth wafer G to epitaxially grow the light-emitting portion 212, an electrode 213, which is transparent and conductive, is formed on the upper surface of the first semiconductor region 2121, and then the silicon (Si) support wafer 211 having a (111), (110), or (100) crystal face is bonded to the electrode 213 through a bonding layer B. Thereafter, the growth wafer G is separated from the light-emitting portion 212 using a CLO technique, the second semiconductor region 2122 is etched to reduce a thickness of the second semiconductor region 2122, an ohmic contact electrode 213, which is transparent and conductive, is formed on the lower surface of the second semiconductor region 2122 with the reduced thickness, and then the silicon (Si) support wafer 211 having a (111), (110), or (100) crystal face is bonded to the electrode 213 through a bonding layer B. Thereafter, the temporary wafer T is separated from the adhesive layer A using an LLO technique, the adhesive layer A is etched and removed, and the bonding layer 230 is deposited and formed on the upper electrode 213, thereby preparing a front wafer 210 with a p-side up form.

Accordingly, when the front wafer 210 has the p-side up form, the front wafer 210 has a structure in which the silicon (Si) support wafer 211 having a (111), (110), or (100) crystal face, the bonding layer B, the electrode 213, the second semiconductor region 2122, the active region 2123, the first semiconductor region 2121, the electrode 213, and the bonding layer 230 are sequentially stacked. The silicon (Si) support wafer 111 has no difference in thermal expansion coefficient when the front wafer 210 is bonded to the silicon (Si) back wafer 220 later, thereby contributing to stabilizing the quality of the vertically stacked microdisplay panel.

Furthermore, in a process of manufacturing the front wafer 210 with the p-side up or n-side up form described above, before the electrode 213 is formed on a surface of the first semiconductor region 2121 or a surface of the second semiconductor region 2122, when the surface of the first semiconductor region 2121 is exposed (p-side up form) or the surface of the second semiconductor region 2122 is exposed (n-side up form), the surfaces may each be polished and smoothly planarized through MP or CMP to have a smooth surface.

Meanwhile, the electrode 213 of the front wafer 210 is formed of a material which is transparent and conductive. Since the following contents are the same as those of the method S100 of manufacturing a microdisplay panel according to the first embodiment of the present invention described above, redundant descriptions thereof will be omitted.

FIG. 28 illustrates that a bonding reinforcement layer is formed on each of an upper and a lower surface of an electrode in the method of manufacturing a microdisplay panel according to first or second embodiment of the present invention. FIG. 29 illustrates various bonding reinforcement layers in the method of manufacturing a microdisplay panel according to the first or second embodiment of the present invention.

As shown in FIGS. 28 and 29, a bonding reinforcement layer 213a may be formed on at least one of an upper and a lower surface of the electrode 213. Since the following contents are the same as those of the bonding reinforcement layer 113a of the method S100 of manufacturing a microdisplay panel according to the first embodiment of the present invention described above, redundant descriptions thereof will be omitted.

The back wafer 220 is a CMOS wafer in which, as an active driving IC driven through an AM method, a plurality of CMOS electrode pads 221 are arrayed on an upper surface thereof. A passivation layer may be formed between the plurality of CMOS electrode pads 221.

Here, the back wafer 220 is prepared as a silicon (Si) wafer having a (100) crystal face and preferably provided as an 8-inch or 12-inch silicon (Si) wafer according to a standard CMOS IC process.

FIG. 25 illustrates a case in which a CMOS electrode pad to which a reflector is applied is a single layer in the method of manufacturing a microdisplay panel according to the first or second embodiment of the present invention. FIG. 26 illustrates a case in which a CMOS electrode pad to which a reflector is applied is a multilayer in the method of manufacturing a microdisplay panel according to the first or second embodiment of the present invention. FIG. 27 illustrates the reflectivity of reflectors applicable to a CMOS electrode pad in the method of manufacturing a microdisplay panel according to the first or second embodiment of the present invention.

As shown in FIGS. 25 and 26, the CMOS electrode pad 221 may be formed as a single layer or multiple layers, and the CMOS electrode pad 221 may include a reflective layer that reflects light generated from the light-emitting portion 212. Since the following contents are the same as those of the reflective layer in the method S100 of manufacturing a microdisplay panel according to the first embodiment of the present invention described above, redundant descriptions thereof will be omitted.

The second operation S220 is an operation of vertically stacking a plurality of light-emitting portions 212 and a plurality of bonding layers 230 on the back wafer 220 by repeating a process of bonding an inverted front wafer 210 onto the back wafer 220 through the bonding layer 230 such that the light-emitting portion 212 of the front wafer 210 faces the CMOS electrode pad 221 of the back wafer 220, that is, the light-emitting portion 212 of the front wafer 210 and the CMOS electrode pad 221 of the back wafer 220 face each other, and then removing the support wafer 211.

Here, since the support wafer 211 of the front wafer 210 is a silicon (Si) wafer having a (111), (110), or (100) crystal face, and the back wafer 220 is also a silicon (Si) wafer having a (100) crystal face, there is no difference in thermal expansion coefficient during bonding, thereby contributing to stabilizing the quality of the vertically stacked microdisplay panel.

In this case, the second operation S220 uses properties in which smooth surfaces adhere to each other due to van der Waals forces without using a high voltage or an external electric field. Accordingly, it is preferable that, before the front wafer 210 and the back wafer 220 are bonded through the bonding layer 230, a CMP process is introduced so that the roughness of each bonding surface is very low (Rq<0.5 nm @ 2 μm×2 μm) and there are no particles such as impurities between surfaces. To this end, in the second operation S220, before the front wafer 210 is bonded to the back wafer 220, surfaces of the bonding layer 230 of the front wafer 210 and the bonding layer 230 of the back wafer 220 may each be polished and smoothly planarized through MP or CMP.

Here, the bonding layer 230 is formed of a ceramic material that is optically transparent and electrically conductive, that is, transparent and conductive. Here, the term “optically transparent” means being transparent (transmittance of 80% or more) or translucent (transmittance of 50% or more) in a wavelength band of light (including visible light) used in an optical exposure (photolithography) process, and the term “electrically conductive” means having an electrical resistance of less than 10⁻³ Ω/cm. The ceramic material with transparency and conductivity includes a TCO, a TCN, and a TCON.

More specifically, as shown in FIGS. 21 to 23, in the second operation S220, after the first front wafer 210a is bonded onto the back wafer 220 through the bonding layer 230 such that the first light-emitting portion 212a of the first front wafer 210a with an n-side up (or p-side up) form faces the CMOS electrode pad 221 of the back wafer 220, the support wafer 211 is removed using a CLO technique or the like, and the bonding layer B is etched and removed.

Thereafter, after the second front wafer 210b is bonded onto the back wafer 220 on which the first light-emitting portion 212a having electrodes 213 formed on each of an upper surface and lower surface thereof is bonded through the bonding layer 230 such that the second light-emitting portion 212b of the second front wafer 210b with an n-side up (or p-side up) form faces the CMOS electrode pad 221 of the back wafer 220, the support wafer 211 is removed using a CLO technique or the like, and the bonding layer B is etched and removed.

Afterwards, after the third front wafer 210c is bonded onto the back wafer 220 on which the second light-emitting portion 212b having electrodes 213 formed on each of an upper surface and lower surface thereof is bonded through the bonding layer 230 such that the third light-emitting portion 212c of the third front wafer 210c with an n-side up (or p-side up) form faces the CMOS electrode pad 221 of the back wafer 220, the support wafer 211 is removed using a CLO technique or the like, and the bonding layer B is etched and removed, thereby obtaining a structure in which the back wafer 220, the bonding layer 230, the first light-emitting portion 212a having electrodes 213 formed on each of the upper surface and lower surface thereof, the bonding layer 230, the second light-emitting portion 212b having electrodes 213 formed on each of the upper surface and lower surface thereof, the bonding layer 230, and the third light-emitting portion 212c having electrodes 213 formed on each of the upper surface and lower surface thereof are vertically stacked. When the first light-emitting portion 212a, the second light-emitting portion 212b, and the third light-emitting portion 212c emit light simultaneously, white light is emitted.

In this case, considering a wavelength of light, it is preferable that first color light of the first light-emitting portion 212a of a lower layer is red light with a long wavelength, second color light of the second light-emitting portion 212b of an intermediate layer is green, and third color light of the third light-emitting portion 212c of an upper layer is blue with a short wavelength, but the present invention is not limited thereto.

Thereafter, after the plurality of front wafers 210 are bonded to the back wafer 220 in the second operation S220, it is necessary to perform heat treatment on the bonding layer 230 at a temperature of less than 400° C. such that a CMOS circuit of the back wafer 220 is not damaged, and a structure is obtained in which a bonding layer 230 disposed on the back wafer 220, a first light-emitting portion 212a disposed on the bonding layer 230, a bonding layer 230 disposed on the first light-emitting portion 212a, a second light-emitting portion 212b disposed on the bonding layer 230, a bonding layer 230 disposed on the second light-emitting portion 212b, and a third light-emitting portion 212c disposed on the bonding layer 230 are sequentially stacked. Also, a structure is obtained in which a bonding reinforcement layer 213a is formed on at least one of the upper surface and the lower surface of the electrode 213. That is, a transparent stack layer structure is formed on a CMOS IC wafer consisting of an array of CMOS electrode pads 221, thereby forming an engineering monolithic epitaxy wafer structure of the present invention.

The third operation S230 is an operation of etching the plurality of vertically stacked light-emitting portions 212 and bonding layers 230, the electrode 213, and the bonding reinforcement layer 213a to be divided into preset units (pixel or subpixel units) to arrange a plurality of LED stacks on a plurality of CMOS electrode pads 221, thereby eliminating the need for a conventional process of arranging the LED stacks of the front wafer 210 and the CMOS electrode pads 221 of the back wafer 220.

That is, the LED stack in the present invention means that the plurality of vertically stacked light-emitting portions 212 and bonding layers 230, the electrode 213, and the bonding reinforcement layer 213a are vertically etched and then divided into preset units (pixel or subpixel units). In the third operation S230, the light-emitting portion 212, the bonding layer 230, the electrode 213, and the bonding reinforcement layer 213a are vertically etched until a surface of the back wafer 220 or an area adjacent thereto is exposed to align the plurality of LED stacks on the arrayed, that is, arranged, CMOS electrode pads 221.

In this case, the light-emitting portion 212, the bonding layer 230, the electrode 213, and the bonding reinforcement layer 213a of the present invention are all transparent to transmit visible light, and thus there is an advantage in that there is no arrangement error issue in an exposure process. In addition, since a ceramic material is used rather than a metal, both the bonding layer 230 and the electrode 213 of the present invention are easy to etch in a plasma dry process, and there is an advantage in that there is no problem of re-deposition of etch by-products.

The fourth operation S240 is an operation of forming a mold portion M that fills a space between the plurality of arranged LED stacks, forming a common electrode 240 on the plurality of LED stacks, and forming a color filter 250 on the common electrode 240.

More specifically, in the fourth operation S240, after the mold portion M is formed to fill the space between the plurality of arranged LED stacks, and the mold potion M is etched such that upper portions of the plurality of LED stacks are exposed, the common electrode 240 is formed on the exposed upper portions of the plurality of LED stacks, and the color filter 250 is formed on the common electrode 240, thereby completing a vertically stacked LEDoS structure. Here, similar to the electrode 213, the common electrode 240 may be formed of a material that is transparent and conductive. When the common electrode 240 is an anode, a material of the common electrode 240 may include NiO, PtO, PdO, AgO₂, Au, Rh₂O₃, RuO₂, In₂O₃, SnO₂, ZnO, IZO, ITO, and IGZO, and when the common electrode 240 is a cathode, the material of the common electrode 240 may include TiN, CrN, VN, In₂O₃, SnO₂, ZnO, IZO, ITO, and IGZO.

In addition, a surface of the common electrode 240 may also be polished and smoothly planarized through MP or CMP.

In addition, the color filters 250 provide light in different wavelength bands when light emitted from the light-emitting portion 212 is incident. For example, the color filters 250 may each provide light such as blue light, green light, or red light, and a portion at which the color filter 250 is not formed may provide white light. Meanwhile, the wavelength band of light provided from the color filter 250 may vary according to the design.

The color filter 250 described above is basically a thin film type containing an organic dye or pigment in a photoresist, but it is more preferable to use inorganic quantum dots for manufacturing a microdisplay including pixels with a size of less than 3 μm. In particular, before the color filter 250 is formed on the common electrode 240, it is preferable that a thin film with a thickness of 100 nm or less is formed using Al₂O₃, SiNₓ, or SiO₂ through an atomic layer deposition (ALD) device or the like to improve the thin film quality of the color filter 250.

Furthermore, although not shown, a protection layer may be additionally formed using a transparent organic material to protect the color filter 250 from the atmospheric environment.

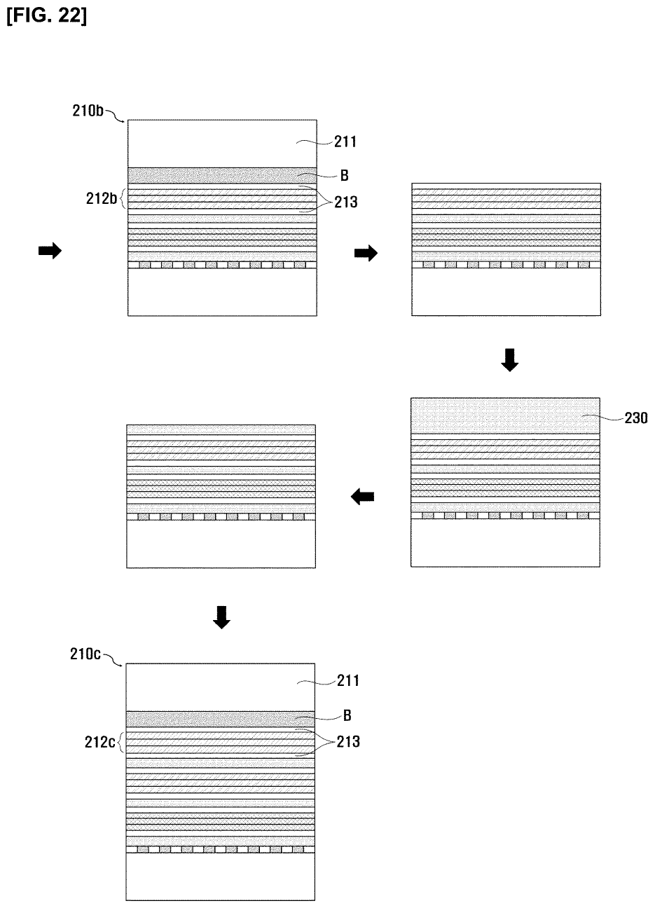

FIG. 24 illustrates a vertically stacked microdisplay panel manufactured according to the method of manufacturing a microdisplay panel according to the second embodiment of the present invention.

As shown in FIG. 24, the vertically stacked microdisplay panel, which is manufactured according to the method S200 of manufacturing a microdisplay panel according to the second embodiment of the present invention which includes the first operation S210, the second operation S220, the third operation S230, and the fourth operation S240 as described above, includes the back wafer 220 having a plurality of CMOS electrode pads 221 arranged on an upper surface thereof, a bonding layer 230 disposed on the back wafer 220, a first light-emitting portion 212a disposed on the bonding layer 230, a bonding layer 230 disposed on the first light-emitting portion 212a, a second light-emitting portion 212b disposed on the bonding layer 230, a bonding layer 230 disposed on the second light-emitting portion 212b, a third light-emitting portion 212c disposed on the bonding layer 230, a common electrode 240 disposed on the third light-emitting portion 212c, and a color filter 250 disposed on the common electrode 240. In this case, an electrode 213 is formed on at least one of an upper surface and a lower surface of each of the first light-emitting portion 212a, the second light-emitting portion 212b, and the third light-emitting portion 212c, and a bonding reinforcement layer 213a is formed on at least one of an upper surface and a lower surface of the electrode 213. Furthermore, the CMOS electrode pad 221 may include a reflective layer that reflects light generated from the light-emitting portion 212.

Here, the bonding layer 230 and the electrode 213 are formed of a ceramic material that is transparent and conductive, and the plurality of vertically stacked light-emitting portions 212 and bonding layers 230, the electrode 213, and the bonding reinforcement layer 213a are etched and divided into preset units, thereby obtaining a structure in which a plurality of LED stacks are arranged on the plurality of arranged CMOS electrode pads 221. Accordingly, an LEDoS structure of a microdisplay panel 200 according to the second embodiment of the present invention is completed.

As described above, although all the components constituting embodiments disclosed herein were described as being combined or combined to operate as one, the present invention is not necessarily limited to these embodiments. That is, one or more of all the components may be selectively combined to operate as one without departing from the scope of the purpose of the present invention.

In addition, the terms “include,” “consist,” or “have” as described above mean that a corresponding component may be intrinsic, unless specifically stated otherwise, and it should interpreted as including other components rather than excluding other components. All terms including technical or scientific terms have the same meanings as those commonly understood by those skilled in the art to which the present invention pertains, unless defined otherwise. Commonly used terms, such as terms defined in a dictionary, should be interpreted as being consistent with the contextual meaning of the related art and are not interpreted in an ideal or excessively formal meaning unless explicitly defined herein.

The above description is merely illustrative of the technical idea of the present invention, and those skilled in the art to which the present invention pertains may make various modifications and variations without departing from the essential characteristics of the present invention.

Accordingly, the embodiments disclosed in the present invention are not intended to limit the technical idea of the present invention, but are for illustrative purposes, and the scope of the technical idea of the present invention is not limited by these embodiments. The spirit and scope of the present invention should be interpreted by the appended claims and encompass all equivalents falling within the scope of the appended claims.

1. A method of manufacturing a microdisplay panel, which does not require a process of arranging light-emitting diode (LED) stacks and complementary metal oxide semiconductor (CMOS) electrode pads, the method comprising:
a first operation of preparing a front wafer including a support wafer, and a light-emitting portion, and an electrode, and preparing a back wafer having a plurality of CMOS electrode pads arranged at regular intervals on an upper surface thereof, wherein the light-emitting portion is disposed on the support wafer and formed by epitaxially growing a Group III-IV compound semiconductor, wherein the electrode that is in ohmic contact with and electrically connected to the light-emitting portion is formed on at least one of an upper surface and a lower surface of the light-emitting portion, wherein the electrode is formed of a material that is optically transparent and electrically conductive;
a second operation of bonding the front wafer onto the back wafer through a bonding layer such that the light-emitting portion faces the CMOS electrode pad, and then removing the support wafer, wherein the bonding layer is formed of a material that is optically transparent and electrically conductive; and
a third operation of etching the light-emitting portion, the electrode and the bonding layer to be divided into preset units according to the positions of the plurality of CMOS electrode pads arranged at regular intervals, and arranging the plurality of LED stacks on the plurality of CMOS electrode pads,
wherein, in the first operation and the second operation, the light-emitting portion and the electrode in the front wafer are not etched in preset units.
wherein, in the third operation, utilizing the fact that the light-emitting portion, the electrode, and the bonding layer are all optically transparent, the light-emitting portion, the electrode, and the bonding layer are etched into preset units according to the positions of the plurality of CMOS electrode pads aligned at regular intervals.

2. The method of claim 1, wherein the bonding layer is formed of a ceramic material that is optically transparent and electrically conductive.

3. The method of claim 2, wherein the ceramic material is a transparent conductive oxide (TCO), a transparent conductive nitride (TCN), or a transparent conductive oxynitride (TCON).

4. The method of claim 1, wherein, in the second operation, before the bonding of the front wafer onto the back wafer, surfaces of the bonding layer of the front wafer and the bonding layer of the back wafer are each polished and planarized.

5-8. (canceled)

9. The method of claim 1, wherein a surface of the electrode is polished and planarized.

10. A method of manufacturing a microdisplay panel, which does not require a process of arranging light-emitting diode (LED) stacks and complementary metal oxide semiconductor (CMOS) electrode pads, the method comprising:
a first operation of preparing a plurality of front wafers, each including a support wafer, a light-emitting portion, and an electrode, and preparing a back wafer having a plurality of CMOS electrode pads arranged at regular intervals on an upper surface thereof, wherein the light-emitting portion is disposed on the support wafer and formed by epitaxially growing a Group III-IV compound semiconductor, wherein the electrode that is in ohmic contact with and electrically connected to the light-emitting portion is formed on at least one of an upper surface and a lower surface of the light-emitting portion, wherein the electrode is formed of a material that is optically transparent and electrically conductive, wherein the front wafers each emit different colors;
a second operation of vertically stacking a plurality of light-emitting portion, electrode and bonding layer on the back wafer by repeatedly bonding the front wafer onto the back wafer through a bonding layer and then removing the support wafer, wherein the bonding layer is formed of a material that is optically transparent and electrically conductive; and
a third operation of etching the plurality of vertically stacked light-emitting portions, electrodes and bonding layers to be divided into preset units according to the positions of the plurality of CMOS electrode pads arranged at regular intervals, and arranging the plurality of LED stacks on the plurality of CMOS electrode pads,
wherein, in the first operation and the second operation, the light-emitting portion and the electrode in the front wafer are not etched in preset units,
wherein, in the third operation, utilizing the fact that the light-emitting portion, the electrode, and the bonding layer are all optically transparent, the light-emitting portion, the electrode, and the bonding layer are etched into preset units according to the positions of the plurality of CMOS electrode pads aligned at regular intervals.

11. The method of claim 10, wherein the bonding layer is formed of a ceramic material that is optically transparent and electrically conductive.

12. The method of claim 11, wherein the ceramic material is a transparent conductive oxide (TCO), a transparent conductive nitride (TCN), or a transparent conductive oxynitride (TCON).

13. The method of claim 10, wherein the plurality of front wafers including a first front wafer that emits light having a first color, a second front wafer that emits light having a second color different from the first color, and a third front wafer that emits light having a third color different from the first and second colors.

14. The method of claim 10, the fourth operation of a common electrode is formed on the upper portions of the plurality of LED stacks, and the color filter is formed on the common electrode.

15. The method of claim 10, wherein, in the second operation, before the bonding of the front wafer onto the back wafer, surfaces of the bonding layer of the front wafer and the bonding layer of the back wafer are each polished and planarized.

16. The method of claim 10, wherein a surface of the electrode is polished and planarized.

17. A method of manufacturing a microdisplay panel, which does not require a process of arranging light-emitting diode (LED) stacks and complementary metal oxide semiconductor (CMOS) electrode pads, the method comprising:
a first operation of preparing a front wafer including a support wafer, a light-emitting portion, and an electrode, and preparing a back wafer having a plurality of CMOS electrode pads arranged at regular intervals on an upper surface thereof, wherein the light-emitting portion is disposed on the support wafer and formed by epitaxially growing a Group III-IV compound semiconductor, wherein the electrode that is in ohmic contact with and electrically connected to the light-emitting portion is formed on at least one of an upper surface and a lower surface of the light-emitting portion, wherein the electrode is formed of a material that is optically transparent and electrically conductive;
a second operation of bonding the front wafer onto the back wafer through a bonding layer such that the light-emitting portion faces the CMOS electrode pad, and then removing the support wafer, wherein the bonding layer is formed of a material that is optically transparent and electrically conductive; and
a third operation of etching the light-emitting portion, the electrode and the bonding layer to be divided into preset units according to the positions of the plurality of CMOS electrode pads arranged at regular intervals, and arranging the plurality of LED stacks on the plurality of CMOS electrode pads,
wherein, in the first operation and the second operation, the light-emitting portion and the electrode in the front wafer are not etched in preset units,
wherein, in the third operation, utilizing the fact that the light-emitting portion, the electrode, and the bonding layer are all optically transparent, the light-emitting portion, the electrode, and the bonding layer are etched into preset units according to the positions of the plurality of CMOS electrode pads aligned at regular intervals,
wherein the CMOS electrode pad includes a reflective layer that reflects light generated from the light-emitting portion.

18. The method of claim 17, wherein the CMOS electrode pad is formed as a single layer or multiple layers.

19. The method of claim 17, wherein the reflective layer is formed of aluminum (Al).

20. The method of claim 17, wherein the bonding layer is formed of a ceramic material that is optically transparent and electrically conductive.

21. The method of claim 20, wherein the ceramic material is a transparent conductive oxide (TCO), a transparent conductive nitride (TCN), or a transparent conductive oxynitride (TCON).

22. The method of claim 17, wherein, in the first operation, preparing a plurality of front wafers, each emit different colors,
wherein, in the second operation, vertically stacking a plurality of light-emitting portion, electrode and bonding layer on the back wafer by repeatedly bonding the front wafer onto the back wafer through a bonding layer and then removing the support wafer.
wherein, in the third operation, etching the plurality of vertically stacked light-emitting portions, electrodes and bonding layers to be divided into preset units according to the positions of the plurality of CMOS electrode pads arranged at regular intervals.
